(19) United States
(12) Patent Application Publication
(10) Pub. No.: US 2024/0318073 A1
(43) Pub. Date: Sep. 26, 2024

(54) QUANTUM DOT COMPOSITION AND LIGHT-EMITTING DEVICE PREPARED USING THE SAME

(71) Applicants: Samsung Display Co., LTD., Yongin-si (KR); UNIST (ULSAN NATIONAL INSTITUTE OF SCIENCE AND TECHNOLOGY), Ulsan (KR)

(72) Inventors: Wonjun Park, Yongin-si (KR); Bongsoo Kim, Ulsan (KR); Myeongjae Lee, Ulsan (KR); Yunhyuk Ko, Yongin-si (KR); Sehun Kim, Yongin-si (KR); Seonhui Baek, Yongin-si (KR); Yunku Jung, Yongin-si (KR); Hyobin Ham, Ulsan (KR)

(73) Assignees: Samsung Display Co., LTD., Yongin-si (KR); UNIST (ULSAN NATIONAL INSTITUTE OF SCIENCE AND TECHNOLOGY), Ulsan (KR)

(21) Appl. No.: 18/610,489

(22) Filed: Mar. 20, 2024

(30) Foreign Application Priority Data
Mar. 24, 2023 (KR) 10-2023-0038982
Aug. 14, 2023 (KR) 10-2023-0106417

(51) Int. Cl. C09K 11/06; C09K 11/02; H10K 50/115

(52) U.S. Cl. CPC C09K 11/06; C09K 11/02; H10K 50/115

(57) ABSTRACT

Embodiments provide is a quantum dot composition that includes quantum dots, a cross-linking agent including four or more moieties represented by Formula A, and a mixed solvent including a first solvent, a second solvent, and a third solvent. The second solvent has a higher boiling point than the first solvent, the second solvent has a lower surface tension than the first solvent, and the third solvent includes a compound represented by Formula 3. Formula A and Formula 3 are explained in the specification:

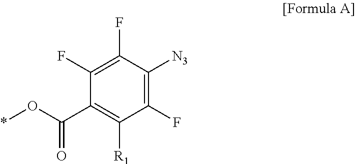

Ar₂—R₂. [Formula 3]

### CROSS-REFERENCE TO RELATED APPLICATION(S)

This application claims priority to and benefits of Korean Patent Application Nos. 10-2023-0038982 and 10-2023-0106417 under 35 U.S.C. § 119, filed on Mar. 24, 2023 and Aug. 14, 2023, respectively, in the Korean Intellectual Property Office, the entire contents of which are incorporated herein by reference.

### BACKGROUND

### 1. Technical Field

Embodiments relate to a quantum dot composition and a light-emitting device prepared by using the same.

### 2. Description of the Related Art

Light-emitting devices are devices using light energy converted from electrical energy. In a light-emitting device, holes provided from an anode move toward an emission layer through a hole transport region, and electrons provided from a cathode move toward an emission layer through an electron transport region. Carriers, such as holes and electrons, recombine in the emission layer to produce excitons. These excitons transition from an excited state to a ground state to thereby generate light. The emission layer of the light-emitting device may include quantum dots. Quantum dots are nanocrystals of semiconductor materials and exhibit a quantum confinement effect. By adjusting sizes of quantum dots, light of a desired wavelength can be obtained, and quantum dots exhibit characteristics such as excellent color purity and high luminescence efficiency. An emission layer including quantum dots may be formed by using a quantum dot composition.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments include a quantum dot composition having an improved curing degree and a light-emitting device prepared by using the same.

Additional aspects will be set forth in part in the description which follows and, in part, will be apparent from the description, or may be learned by practice of the embodiments of the disclosure.

According to embodiments, a quantum dot composition may include:

quantum dots;

a cross-linking agent having four or more moieties each independently represented by Formula A; and

a mixed solvent including a first solvent, a second solvent, and a third solvent, wherein

the second solvent has a higher boiling point than the first solvent,

the second solvent has a lower surface tension than the first solvent, and

the third solvent is a compound represented by Formula 3:

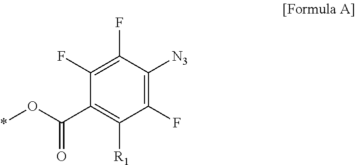

Ar₂—R₂ [Formula 3]

In Formulae A and 3,

R₁ may be hydrogen, deuterium, a halogen, or a C₁-C₁₀ alkyl group,

* indicates a binding site to a neighboring atom,

Ar₂ may be a substituted or unsubstituted C₆-C₃₀ aryl group, and

R₂ may be a linear or branched C₁-C₃₀ alkyl group.

In an embodiment, the cross-linking agent may be a compound represented by Formula 1 or Formula 2:

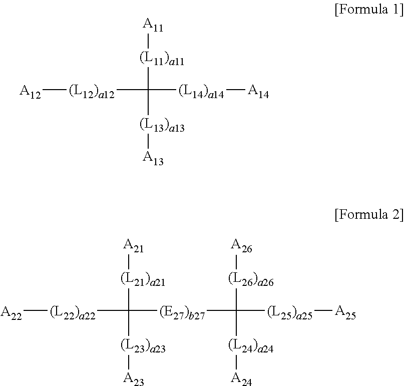

In Formulae 1 and 2,

A₁₁ to A₁₄ may each independently be a group represented by Formula A,

A₂₁ to A₂₆ may each independently be hydrogen or a group represented by Formula A,

at least one of A₂₁ to A₂₃ and at least one of A₂₄ to A₂₆ may each independently be a group represented by Formula A,

L₁₁ to L₁₄ and L₂₁ to L₂₆ may each independently be a direct bond or a C₁-C₃ alkylene group,

E₂₇ may be a —CH₂—O—CH₂— group, a —CH(R₂₇)— group, or a —C(R₂₇)₂— group,

R₂₇ may be a -(L₂₇)ₐ₂₇-A₂₇ group,

L₂₇ may be the same as described in connection with L₂₁,

A₂₇ may be the same as described in connection with A₂₁,

a11 to a14 and a21 to a27 may each independently be 0 or 1,

b27 may be an integer from 1 to 6, and

when A₂₁ is hydrogen, a21 may be 0, when A₂₂ is hydrogen, a22 may be 0, when A₂₃ is hydrogen, a23 may be 0, when A₂₄ is hydrogen, a24 may be 0, when A₂₅ is hydrogen, a25 may be 0, when A₂₆ is hydrogen, a26 may be 0, and when A₂₇ is hydrogen, a27 may be 0.

In an embodiment, the cross-linking agent may be represented by Formula 1; and in Formula 1, L₁₁ to L₁₄ may each independently be a —CH₂— group.

In an embodiment, the cross-linking agent may be represented by Formula 2; and in Formula 2, b27 may be 1, and E₂₇ may be a —CH₂—O—CH₂— group.

In an embodiment, the cross-linking agent may be represented by Formula 2; and in Formula 2, b27 may be 2, and each E₂₇ may independently be a —CH(R₂₇)— group.

In an embodiment, the cross-linking agent may be represented by Formula 2; and in Formula 2, b27 may be 3, and each E₂₇ may independently be a —CH₂—O—CH₂— group or a —C(R₂₇)₂— group.

In an embodiment, in Formula 3, Ar₂ may be a phenyl group; and R₂ may be a methyl group, an ethyl group, a propyl group, a butyl group, a pentyl group, a hexyl group, a heptyl group, an octyl group, a nonyl group, a decyl group, an undecyl group, or a dodecyl group.

In an embodiment, the first solvent may be cyclohexylbenzene, the second solvent may be hexadecane, and the third solvent may be octylbenzene.

In an embodiment, a difference in dispersion (OD) among Hansen solubility parameters (HSP) between the cross-linking agent and the mixed solvent may be equal to or less than about 1.1 MPa^{1/2}.

In an embodiment, the mixed solvent may have a boiling point equal to or greater than about 200° C.

In an embodiment, the quantum dots may emit green light.

In an embodiment, the quantum dots may include a Group II-VI semiconductor compound, a Group III-V semiconductor compound, a Group III-VI semiconductor compound, a Group I-III-VI semiconductor compound, a Group IV-VI semiconductor compound, a Group IV element or compound, or any combination thereof.

In an embodiment, the quantum dots may each further include a ligand on a surface of the quantum dots, and crosslinks may be formed between ligands by the cross-linking agent.

In an embodiment, the ligand may include at least one of dodecanethiol (DDT), zinc oleate (ZnOA), zinc(II) 2-ethylhexanoate (Zn(EHA)), and zinc laurate (Zn(LRA)).

According to embodiments, a light-emitting device may include:

a first electrode on a substrate;

a second electrode facing the first electrode; and

an organic layer between the first electrode and the second electrode and including an emission layer, wherein

the emission layer may be formed by the quantum dot composition.

In an embodiment, the first electrode may be a cathode; the second electrode may be an anode; and the light-emitting device may further include an electron transport region between the first electrode and the emission layer, and a hole transport region between the second electrode and the emission layer.

According to embodiments, an electronic apparatus may include the light-emitting device.

In an embodiment, the electronic apparatus may further include a thin-film transistor, wherein

the thin-film transistor may include a source electrode and a drain electrode, and

the first electrode of the light-emitting device may be electrically connected to at least one of the source electrode and the drain electrode.

In an embodiment, the electronic apparatus may further include a color filter, a color conversion layer, a touch screen layer, a polarizing layer, or any combination thereof.

It is to be understood that the embodiments above are described in a generic and explanatory sense only and not for the purposes of limitation, and the disclosure is not limited to the embodiments described above.

### BRIEF DESCRIPTION OF THE DRAWINGS

The above and other aspects and features of the disclosure will be more apparent by describing in detail embodiments thereof with reference to the accompanying drawings, in which:

FIG. 1 is a schematic cross-sectional view of a light-emitting device according to an embodiment;

FIGS. 2 and 3 are each a schematic cross-sectional view of an electronic apparatus according to an embodiment;

FIG. 4 shows an optical micrograph of an upper surface of a quantum dot layer of each of Examples 1 to 3 and Comparative Examples 1 and 2;

FIG. 5 shows a graph of driving voltage of a light-emitting device of each of Examples 4 and 5 and Comparative Examples 3 to 6; and

FIG. 6 shows a graph of current efficiency of a light-emitting device of each of Examples 4 and 5 and Comparative Examples 3 to 6.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like numbers refer to like elements throughout.

In the specification, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the specification, when an element is “directly on,” “directly connected to,” or “directly coupled to” another element, there are no intervening elements present. For example, “directly on” may mean that two layers or two elements are disposed without an additional element such as an adhesion element therebetween.

In the specification, the expressions used in the singular such as “a,” “an,” and “the,” are intended to include the plural forms as well, unless the context clearly indicates otherwise.

In the specification, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group consisting of” for the purpose of its meaning and interpretation. For example, “at least one of A, B, and C” may be understood to mean A only, B only, C only, or any combination of two or more of A, B, and C, such as ABC, ACC, BC, or CC. When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, ±10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

In the specification, the term “Group II” may include a Group IIA element or a Group IIB element on the IUPAC periodic table, and examples of a Group Il element may include zinc (Zn), cadmium (Cd), mercury (Hg), and copernicium (Cn), but are not limited thereto.

In the specification, the term “Group III” may include a Group IIIA element or a Group IIIB element on the IUPAC periodic table, and examples of a Group III element may include aluminum (AI), indium (In), gallium (Ga), thallium (Tl), and nihonium (Nh), but are not limited thereto.

In the specification, the term “Group V” may include a Group VA element or a Group VB element on the IUPAC periodic table, and examples of a Group V element may include N, P, and As, but are not limited thereto.

In the specification, the term “Group VI” may include a Group VIA element or a Group VIB element on the IUPAC periodic table, and examples of a Group VI element may include oxygen (O), sulfur (S), selenium (Se), and tellurium (Te), but are not limited thereto.

Hereinafter, a quantum dot composition according to an embodiment will be described.

### [Quantum Dot Composition]

A quantum dot composition according to an embodiment may include:

quantum dots;

a cross-linking agent having four or more moieties each independently represented by Formula A; and

a mixed solvent including a first solvent, a second solvent, and a third solvent:

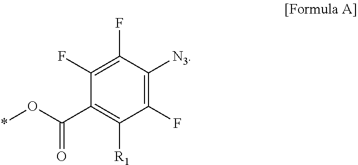

In Formula A,

R₁ may be hydrogen, deuterium, a halogen, or a C₁-C₁₀ alkyl group, and

* indicates a binding site of the moiety to a neighboring atom in the cross-linking agent.

The cross-linking agent crosslinks the ligands of the quantum dots to form a quantum dot layer with a selected curing degree. The moiety represented by Formula A may be a moiety including an azide group that can crosslink the ligands of the quantum dots through a photoreaction. By having four or more moieties represented by Formula A, the cross-linking agent has an excellent cross-linking effect, and compared to cross-linking agents of the related art, the curing degree may be improved when forming a quantum dot layer.

In an embodiment, the cross-linking agent may be a compound represented by Formula 1 or Formula 2:

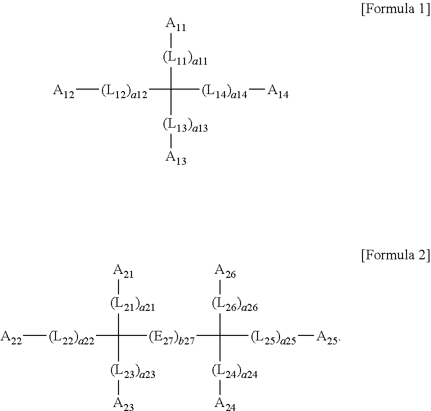

In Formulae 1 and 2,

A₁₁ to A₁₄ may each independently be a group represented by Formula A,

A₂₁ to A₂₆ may each independently be hydrogen or a group represented by Formula A,

at least one of A₂₁ to A₂₃ and at least one of A₂₄ to A₂₆ may each independently be a group represented by Formula A,

L₁₁ to L₁₄ and L₂₁ to L₂₆ may each independently be a direct bond or a C₁-C₃ alkylene group,

E₂₇ may be a —CH₂—O—CH₂— group, a —CH(R₂₇)— group, or a —C(R₂₇)₂— group,

R₂₇ may be a -(L₂₇)ₐ₂₇-A₂₇ group,

L₂₇ may be the same as described in connection with L₂₁,

A₂₇ may be the same as described in connection with A₂₁,

a11 to a14 and a21 to a27 may each independently be 0 or 1,

b27 may be an integer from 1 to 6, and

when A₂₁ is hydrogen, a21 may be 0, when A₂₂ is hydrogen, a22 may be 0, when A₂₃ is hydrogen, a23 may be 0, when A₂₄ is hydrogen, a24 may be 0, when A₂₅ is hydrogen, a25 may be 0, when A₂₆ is hydrogen, a26 may be 0, and when A₂₇ is hydrogen, a27 may be 0.

The cross-linking agent represented by Formula 1 or Formula 2 may have four or more moieties represented by Formula A. For example, a cross-linking agent represented by Formula 2 may have 4 to 8 moieties represented by A.

In an embodiment, the cross-linking agent may be represented by Formula 1; and in Formula 1, L₁₁ to L₁₄ may each be a —CH₂— group.

In an embodiment, the cross-linking agent may be represented by Formula 2; and in Formula 2, b27 may be 1, and E₂₇ may be a —CH₂—O—CH₂— group.

In an embodiment, the cross-linking agent may be represented by Formula 2; and in Formula 2, b27 may be 2, and each E₂₇ may independently be a —CH(R₂₇)— group.

In an embodiment, the cross-linking agent may be represented by Formula 2; and in Formula 2, b27 may be 3, and each E₂₇ may independently be a —CH₂—O—CH₂-group or a —C(R₂₇)₂— group.

In an embodiment, the cross-linking agent may include one of the compounds below or a combination of the compounds below:

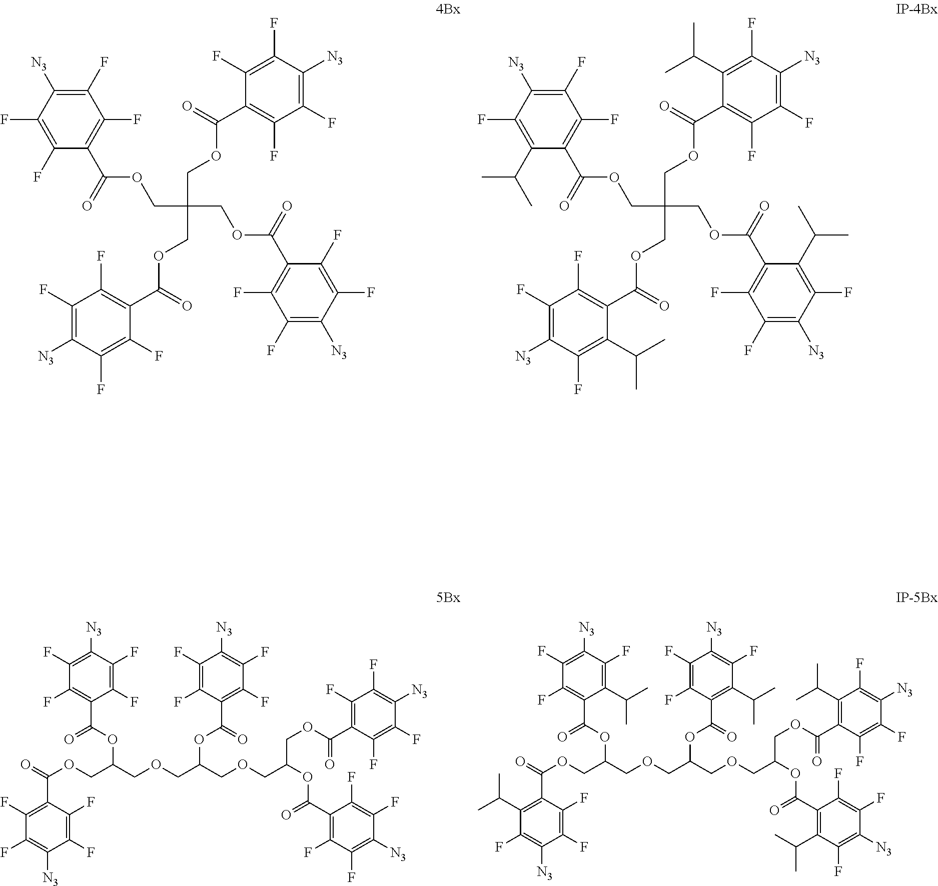

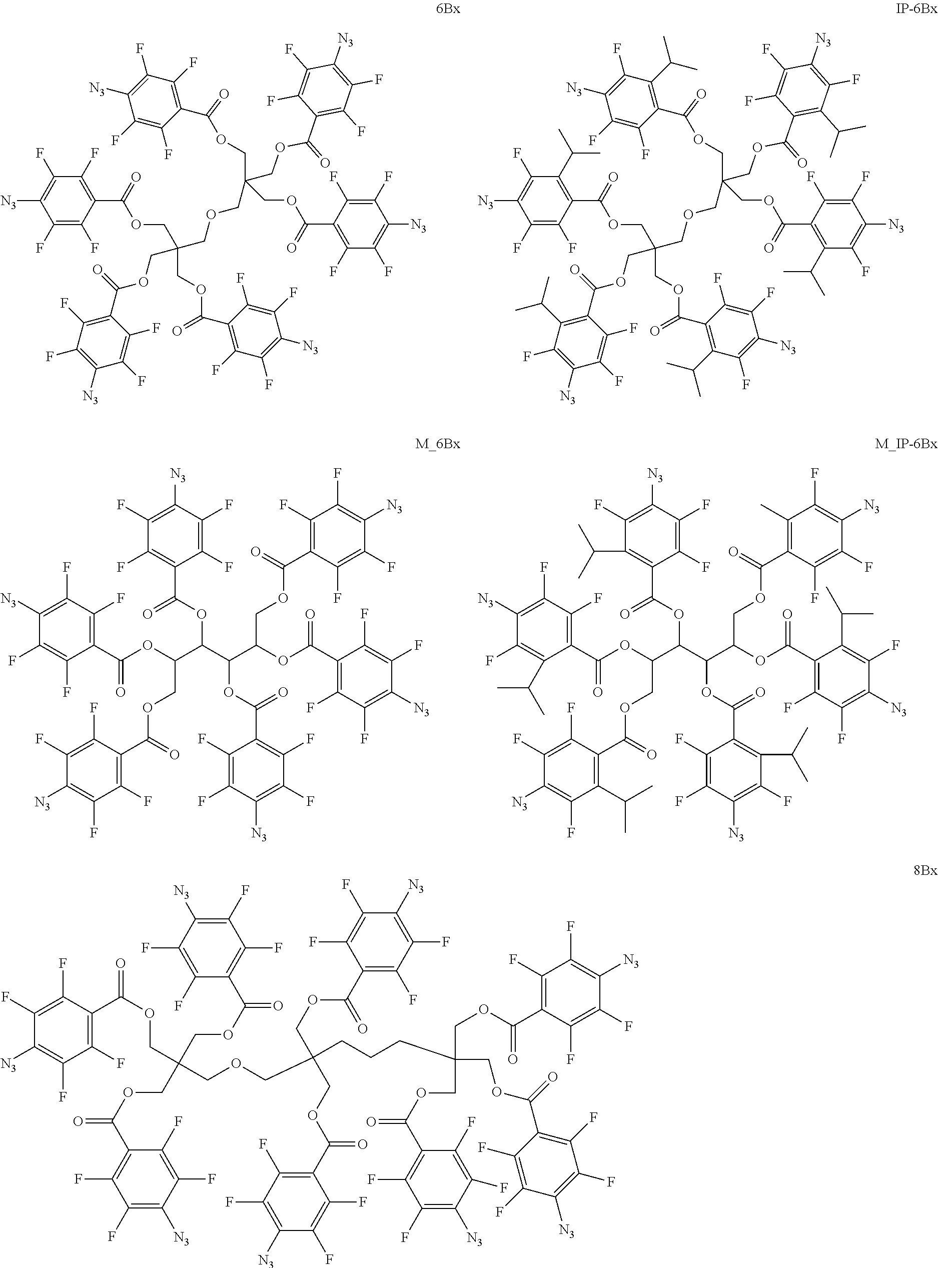

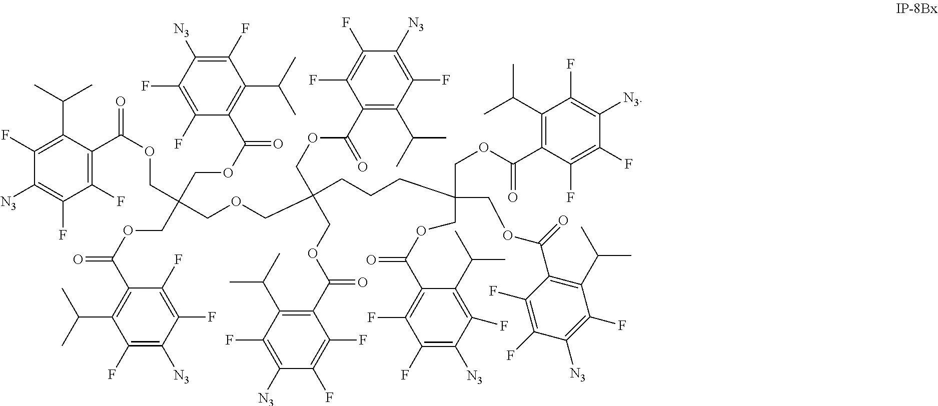 [SMILES: CC(C)c1c(F)c(N=[N+]=[N-])c(F)c(F)c1C(=O)OCC(CCCC(COC(=O)c1c(F)c(F)c(N=[N+]=[N-])c(F)c1C(C)C)(COC(=O)c1c(F)c(F)c(N=[N+]=[N-])c(F)c1C(C)C)COC(=O)c1c(F)c(F)c(N=[N+]=[N-])c(F)c1C(C)C)(COCC(COC(=O)c1c(F)c(F)c(N=[N+]=[N-])c(F)c1C(C)C)(COC(=O)c1c(F)c(F)c(N=[N+]=[N-])c(F)c1C(C)C)COC(=O)c1c(F)c(F)c(N=[N+]=[N-])c(F)c1C(C)C)COC(=O)c1c(F)c(F)c(N=[N+]=[N-])c(F)c1C(C)C]

In the quantum dot composition, the solubility of the first solvent with the cross-linking agent may be higher than the solubility of the second solvent with the cross-linking agent. The second solvent may have a lower vapor pressure than the first solvent, a higher boiling point than the first solvent, and a lower surface tension than the first solvent.

Due to ingredients constituting the mixed solvent, Marangoni flow to the center of the quantum dot composition is promoted, and accordingly, the uniformity and in-pixel uniformity of a thin film produced from the quantum dot composition may be improved, thereby improving the characteristics of a device including the thin film.

In the quantum dot composition, the third solvent may be a compound represented by Formula 3:

Ar₂—R₂ [Formula 3]

In Formula 3,

Ar₂ may be a substituted or unsubstituted C₆-C₃₀ aryl group, and

R₂ may be a linear or branched C₁-C₃₀ alkyl group.

In an embodiment, Ar₂ may be a phenyl group; and R₂ may be a methyl group, an ethyl group, a propyl group, a butyl group, a pentyl group, a hexyl group, a heptyl group, an octyl group, a nonyl group, a decyl group, an undecyl group, or a dodecyl group.

In an embodiment, the first solvent may be cyclohexylbenzene, the second solvent may be hexadecane, and the third solvent may be octylbenzene.

In an embodiment, a difference in dispersion (OD) among Hansen solubility parameters (HSPs) between the cross-linking agent and the mixed solvent may be equal to or less than about 1.1 MPa^{1/2}. The HSPs refer to a numerical representation of the solubility among substances based on dispersion (OD), polarity (OP), and hydrogen-binding (OH) of the substances. In an embodiment, when the difference in dispersion (OD) between the cross-linking agent and the mixed solvent is equal to or less than about 1.1 MPa^{1/2}, the cross-linking agent may have adequate solubility in the mixed solvent, and thus a uniform quantum dot composition may be formed.

In an embodiment, the mixed solvent may have a boiling point equal to or greater than about 200° C. For example, the mixed solvent may have a boiling point in a range of about 200° C. to about 330° C. When the boiling point of the mixed solvent is within the ranges above, a quantum dot layer of good quality may be obtained by applying the quantum dot composition through an ink application process.

In the mixed solvent, an amount of first solvent may be in a range of about 60 wt % to about 70 wt %, based on a total weight of the mixed solvent. In the mixed solvent, an amount of second solvent may be in a range of about 25 wt % to about 30 wt %, based on a total weight of the mixed solvent. In the mixed solvent, an amount of third solvent may be in a range of about 5 wt % to about 10 wt %, based on a total weight of the mixed solvent. The first solvent, the second solvent, and the third solvent in the mixed solvent may be composed in an appropriate ratio to dissolve the quantum dots and the cross-linking agent.

In an embodiment, the quantum dots may be green light-emitting quantum dots that emit green light. A size (diameter) of the quantum dots may be, for example, in a range of about 3 nm to about 10 nm.

In an embodiment, the quantum dots may include a Group II-VI semiconductor compound, a Group III-V semiconductor compound, a Group III-VI semiconductor compound, a Group I-III-VI semiconductor compound, a Group IV-VI semiconductor compound, a Group IV element or compound, or any combination thereof.

In an embodiment, the quantum dots may each further include a ligand on a surface of the quantum dot, and crosslinks may be formed between the ligands by the cross-linking agent.

In an embodiment, the ligand may include at least one of dodecanethiol (DDT), zinc oleate (ZnOA), zinc(II) 2-ethylhexanoate (Zn(EHA)), and zinc laurate (Zn(LRA)).

In an embodiment, the quantum dot composition may further include an appropriate dispersant to improve the dispersion degree of the quantum dot. For example, the dispersant may be a polymer including a carboxylic acid group. An amount of the dispersant may be, based on 100 parts by weight of the quantum dot composition, in a range of about 5 parts by weight to about 30 parts by weight. For example, an amount of the dispersant may be in a range of about 10 parts by weight to about 20 parts by weight, based on 100 parts by weight of the quantum dot composition. When the amount of the dispersant is within any of the ranges above, the aggregation of the quantum dots in the quantum dot composition may be substantially prevented, and the dispersant may thus serve as a protective layer for the quantum dots.

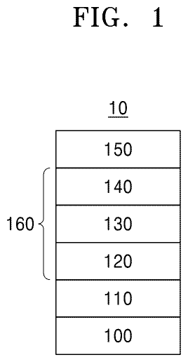

### [Description of FIG. 1]

Hereinafter, a light-emitting device 10 according to an embodiment will be described with reference to FIG. 1. FIG. 1 is a schematic cross-sectional view of a light-emitting device 10 according to an embodiment.

Referring to FIG. 1, the light-emitting device 10 according to an embodiment includes:

a substrate 100;

a first electrode 110 on the substrate 100;

a second electrode 150 facing the first electrode 110; and

an organic layer 160 arranged between the first electrode 110 and the second electrode 150 and including an emission layer 130.

The organic layer 160 may include:

an electron transport region 120 between the emission layer 130 and the first electrode 110; and

a hole transport region 140 between the emission layer 130 and the second electrode 150.

### [Substrate 100]

Any substrate that is generally used in the related art may be used as the substrate 100 for the light-emitting device, and the substrate 100 may be an inorganic substrate or an organic substrate, each having excellent mechanical strength, thermal stability, transparency, surface smoothness, ease of handling, and water resistance.

In an embodiment, the substrate 100 may be a glass substrate or a plastic substrate. In embodiments, the substrate may be a flexible substrate, and may include plastics with excellent heat resistance and durability, such as polyimide, polyethylene terephthalate (PET), polycarbonate, polyethylene naphthalate, polyarylate (PAR), polyetherimide, or any combination thereof.

### [First Electrode 110]

The first electrode 110 on the substrate may be a reflective electrode, a semi-transmissive electrode, or a transmissive electrode. In an embodiment, when the first electrode 110 is a transmissive electrode, a material for forming the first electrode 110 may include indium tin oxide (ITO), indium zinc oxide (IZO), tin oxide (SnO₂), zinc oxide (ZnO), or any combination thereof. In embodiments, when the first electrode 110 is a semi-transmissive electrode or a reflective electrode, a material for forming the first electrode 110 may include magnesium (Mg), silver (Ag), aluminum (AI), aluminum-lithium (Al—Li), calcium (Ca), magnesium-indium (Mg-In), magnesium-silver (Mg—Ag), or any combination thereof. In an embodiment, the first electrode may be a cathode.

The first electrode 110 may have a single-layered structure consisting of a single layer or a multi-layered structure including two or more layers. For example, the first electrode 110 may have a three-layered structure of ITO/Ag/ITO.

### [Electron Transport Region 120 in Organic Layer 160]

The electron transport region 120 may be arranged on the first electrode 110.

The electron transport region 120 may have a structure consisting of a layer consisting of a single material, a structure consisting of a layer including different materials, or a structure including multiple layers including different materials.

The electron transport region 120 may include a buffer layer, a hole blocking layer, an electron control layer, an electron transport layer, an electron injection layer, or any combination thereof.

In embodiments, the electron transport region 120 may have an electron injection layer/electron transport layer structure, a hole injection layer/electron transport layer/electron blocking layer structure, an electron injection layer/electron transport layer/electron control layer structure, or an electron injection layer/electron transport layer/buffer layer structure, wherein the layers of each structure may be stacked from the first electrode 110 in its respective stated order, but the structure of the electron transport region is not limited thereto.

The electron transport region 120 may include a metal oxide, and a metal of the metal oxide may include Zn, Ti, Zr, Sn, W, Ta, Ni, Mo, Cu, Mg, Co, Mn, Y, Al, or any combination thereof. In an embodiment, the electron transport region may include a metal sulfide, such as CuSCN or the like.

The electron transport region 120 (e.g., an electron injection layer or an electron transport layer included in the electron transport region 120) may include an electron transport compound represented by Formula 30:

MₚO_{q} [Formula 30]

In Formula 30,

M may be Zn, Ti, Zr, Sn, W, Ta, Ni, Mo, Cu, or V, and

p and q may each independently be an integer from 1 to 5.

In an embodiment, the electron transport compound may be represented by Formula 30-1:

Zn₍₁₋ᵣ₎M′ᵣO [Formula 30-1]

In Formula 30-1,

M′ may be Mg, Co, Ni, Zr, Mn, Sn, Y, Al, or any combination thereof, and

r may be a number greater than 0 and equal to or less than 0.5.

In an embodiment, the electron transport region may include ZnO or ZnMgO.

### [Emission Layer 130]

The emission layer 130 may be formed from the quantum dot composition.

In the specification, a quantum dot may be a crystal of a semiconductor compound, and may include any material capable of emitting light of various emission wavelengths according to a size of the crystal.

The quantum dots included in the emission layer 130 may include a Group II-VI semiconductor compound, a Group III-V semiconductor compound, a Group III-VI semiconductor compound, a Group I-III-VI semiconductor compound, a Group IV-VI semiconductor compound, a Group IV element or compound, or any combination thereof.

Examples of a Group II-VI semiconductor compound may include: a binary compound, such as CdS, CdSe, CdTe, ZnS, ZnSe, ZnTe, ZnO, HgS, HgSe, HgTe, MgSe, MgS, and the like; a ternary compound, such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and the like; a quaternary compound, such as CdZnSeS, CdZnSeTe, CdZnSTe, CdHgSeS, CdHgSeTe, CdHgSTe, HgZnSeS, HgZnSeTe, HgZnSTe, and the like; or any combination thereof.

Examples of a Group III-V semiconductor compound may include: a binary compound, such as GaN, GaP, GaAs, GaSb, AlN, AlP, AlAs, AlSb, InN, InP, InAs, InSb, and the like; a ternary compound, such as GaNP, GaNAs, GaNSb, GaPAs, GaPSb, AlNP, AlNAs, AlNSb, AlPAS, AlPSb, InGaP, InNP, InAlP, InNAs, InNSb, InPAS, InPSb, and the like; a quaternary compound, such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and the like; or any combination thereof. In an embodiment, a Group III-V semiconductor compound may further include a Group II element. Examples of a Group III-V semiconductor compound further including a Group II element may include InZnP, InGaZnP, InAlZnP, and the like.

Examples of a Group III-VI semiconductor compound may include: a binary compound, such as GaS, GaSe, GazSes, GaTe, InS, InSe, In₂S₃, In₂Se₃, InTe, and the like; a ternary compound, such as InGaS₃, InGaSe₃, and the like; or any combination thereof.

Examples of a Group I-III-VI semiconductor compound may include: a ternary compound, such as AgInS, AgInS₂, CuInS, CuInS₂, CuGaO₂, AgGaO₂, AgAlO₂, and the like; or any combination thereof.

Examples of a Group IV-VI semiconductor compound may include: a binary compound, such as SnS, SnSe, SnTe, PbS, PbSe, PbTe, and the like; a ternary compound, such as SnSeS, SnSeTe, SnSTe, PbSeS, PbSeTe, PbSTe, SnPbS, SnPbSe, SnPbTe, and the like; a quaternary compound, such as SnPbSSe, SnPbSeTe, SnPbSTe, and the like; or any combination thereof.

Examples of a Group IV element or compound may include: a single element material, such as Si, Ge, etc.; a binary compound, such as SiC, SiGe, etc.; or any combination thereof.

Each element included in a multi-element compound, such as a binary compound, a ternary compound, or a quaternary compound, may be present in a particle at a uniform concentration or at a non-uniform concentration.

In embodiments, the quantum dots may have a single structure in which the concentration of each element in the quantum dots is uniform, or the quantum dots may have a core-shell structure. In an embodiment, in case that the quantum dot has a core-shell structure, a material included in the core and a material included in the shell may be different from each other.

In an embodiment, the core may include at least one of Zn, Te, Se, Cd, In, and P. For example, the core may include InP, InZnP, ZnSe, ZnTeS, ZnSeTe, or any combination thereof.

The shell of a quantum dot may serve as a protective layer that prevents chemical denaturation of the core to maintain semiconductor characteristics, and/or may serve as a charging layer that imparts electrophoretic characteristics to the quantum dot. The shell may be single-layered or multi-layered. An interface between the core and the shell may have a concentration gradient in which the concentration of an element that is present in the shell decreases toward the core.

Examples of a shell of a quantum dot may include a metal oxide, a metalloid oxide, a non-metal oxide, a semiconductor compound, or a combination thereof. Examples of a metal oxide, a metalloid oxide, or a non-metal oxide may include: a binary compound, such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, and the like; a ternary compound, such as MgAl₂O₄, CoFe₂O₄, NiFe₂O₄, CoMn₂O₄, and the like; or any combination thereof.

Examples of a semiconductor compound may include a Group II-VI semiconductor compound, a Group III-V semiconductor compound, a Group III-VI semiconductor compound, a Group I-III-VI semiconductor compound, a Group IV-VI semiconductor compound, or any combination thereof. For example, the semiconductor compound may be CdS, CdSe, CdTe, ZnS, ZnSe, ZnTe, ZnSeS, ZnTeS, ZnSeTe, GaAs, GaP, GaSb, HgS, HgSe, HgTe, InAs, InP, InGaP, InSb, AlAs, AlP, AlSb, or any combination thereof.

In an embodiment, the shell may have a composition that is different from a composition of the core, and the shell may include ZnS, ZnSe, ZnSeS, ZnTeS, ZnSeTe, or any combination thereof.

The quantum dots may have a full width at half maximum (FWHM) of an emission wavelength spectrum equal to or less than about 45 nm. For example, the quantum dots may have a FWHM of an emission wavelength spectrum equal to or less than about 40 nm. For example, the quantum dots may have a FWHM of an emission wavelength spectrum equal to or less than about 30 nm. When the FWHM of the quantum dots is within any of these ranges, color purity or color reproducibility may be improved. Light emitted through the quantum dots may be emitted in all directions, so that a wide viewing angle may be improved.

In an embodiment, a diameter of a quantum dot may be in a range of about 1 nm to about 20 nm. When the average diameter of the quantum dots is within this range, specific characteristics of the quantum dots may be achieved, and excellent dispersibility of the quantum dots in the composition may be obtained. In embodiments, the quantum dots may be in the form of a spherical particle, a pyramidal particle, a multi-arm particle, a cubic nanoparticle, a nanotube particle, a nanowire particle, a nanofiber particle, or a nanoplate particle.

By controlling the size of the quantum dot, an energy band gap may be adjustable so that light having various wavelength bands may be obtained from the emission layer including the quantum dot. Accordingly, by using quantum dots of different sizes, a light-emitting device that emits light of various wavelengths may be implemented. In an embodiment, the size of quantum dots may be selected so that the quantum dots may emit red light, green light, and/or blue light. In an embodiment, the size of quantum dots may be configured to emit white light by combining light of various colors.

The quantum dots may be synthesized by a wet chemical process, a metal organic chemical vapor deposition process, a molecular beam epitaxy process, or any process similar thereto.

The wet chemical process is a method that includes mixing a precursor material with an organic solvent and growing quantum dot particle crystals. When the crystal grows, the organic solvent naturally serves as a dispersant coordinated on the surface of the quantum dot crystal and controls the growth of the crystal so that the growth of quantum dot particles can be controlled through a process which costs less, and may be more readily performed than vapor deposition methods, such as metal organic chemical vapor deposition (MOCVD) or molecular beam epitaxy (MBE).

The emission layer 130 may include a monolayer of the quantum dots. For example, the emission layer 130 may include 2 to 20 monolayers of the quantum dots.

A thickness of the emission layer may be in a range of about 5 nm to about 200 nm. For example, the thickness of the emission layer may be in a range of about 10 nm to about 150 nm. For example, the thickness of the emission layer may be in a range of about 10 nm to about 100 nm.

The emission layer 130 may be formed by using the quantum dot composition according to the aforementioned embodiment. The emission layer 130 may be formed by using the quantum dot composition according to an inkjet process. The emission layer 130 formed from the quantum dot composition has an improved degree of curing, and thus, the phenomenon of dissolution of the emission layer 130 by a solvent, which may occur when the hole transport region is formed on the emission layer by a solution process, may be prevented or minimized, thereby improving efficiency of the light-emitting device.

### [Hole Transport Region 140 in Organic Layer 160]

The hole transport region 140 may have a structure consisting of a layer consisting of a single material, a structure consisting of a layer including different materials, or a structure including multiple layers including different materials.

The hole transport region 140 may include a hole injection layer, a hole transport layer, an emission auxiliary layer, an electron blocking layer, or any combination thereof.

The hole injection layer, the hole transport layer, the emission auxiliary layer, and/or the electron blocking layer may be prepared by using the quantum dot composition for the light-emitting device according to an embodiment.

In embodiments, the hole transport region 140 may have a multi-layered structure including a hole injection layer/hole transport layer structure, a hole injection layer/hole transport layer/emission auxiliary layer structure, a hole injection layer/emission auxiliary layer structure, or a hole injection layer/hole transport layer/electron-blocking layer structure, wherein the layers of each structure may be stacked from the emission layer in its respective stated order, but the structure of the hole transport region is not limited thereto.

The hole transport region 140 may include a compound represented by Formula 201, a compound represented by Formula 202, or any combination thereof:

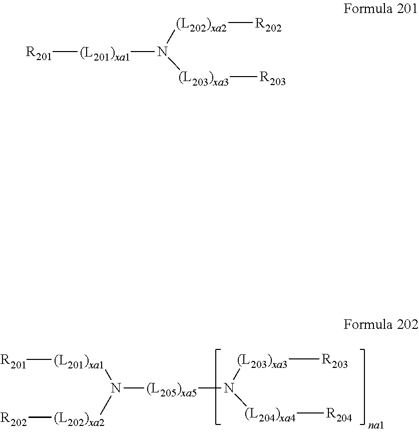

In Formulae 201 and 202,

L₂₀₁ to L₂₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,

L₂₀₅ may be *—O—**, *—S—**, *—N(Q₂₀₁)—*′, a C₁-C₂₀ alkylene group unsubstituted or substituted with at least one R₁₀ₐ, a C₂-C₂₀ alkenylene group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ,

xa1 to xa4 may each independently be an integer from 0 to 5,

xa5 may be an integer from 1 to 10,

R₂₀₁ to R₂₀₄ and Q₂₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,

R₂₀₁ and R₂₀₂ may optionally be linked to each other, via a single bond, a C₁-C₅ alkylene group unsubstituted or substituted with at least one R₁₀ₐ, or a C₂-C₅ alkenylene group unsubstituted or substituted with at least one R₁₀ₐ, to form a C₈-C₆₀ polycyclic unsubstituted or substituted with at least one R₁₀ₐ (for example, a carbazole group),

R₂₀₃ and R₂₀₄ may optionally be linked to each other via a single bond, a C₁-C₅ alkylene group unsubstituted or substituted with at least one R₁₀ₐ, or a C₂-C₅ alkenylene group unsubstituted or substituted with at least one R₁₀ₐ, to form a C₈-C₆₀ polycyclic group unsubstituted or substituted with at least one R₁₀ₐ, and

na1 may be an integer from 1 to 4.

In embodiments, the compound represented by Formula 201 and the compound represented by Formula 202 may each independently include at least one of groups represented by Formulae CY201 to CY217:

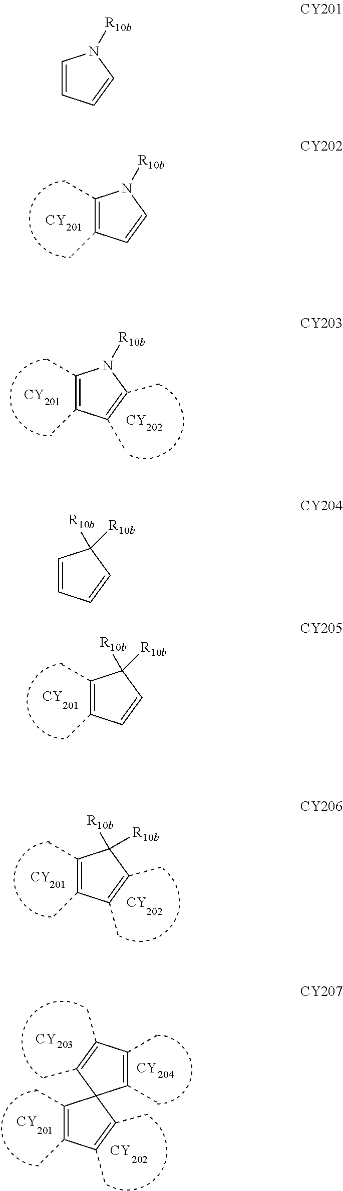

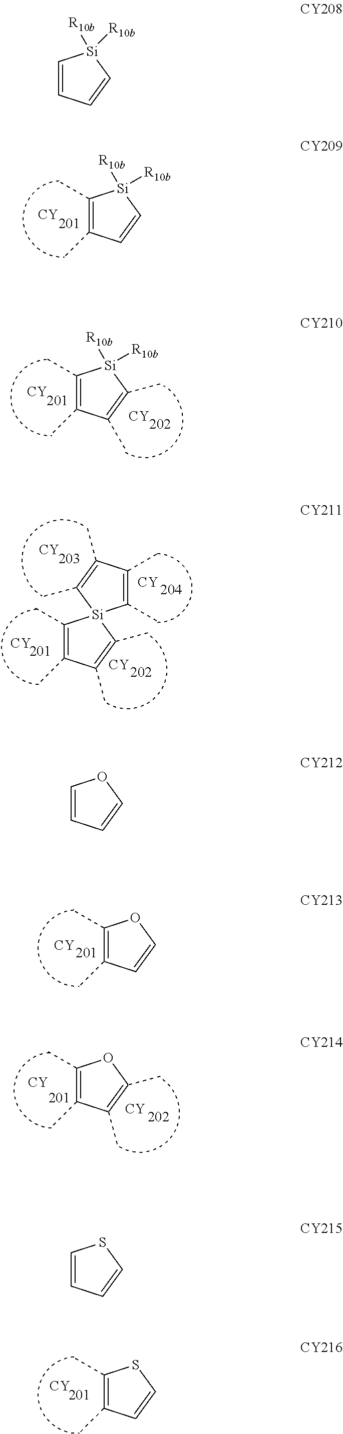

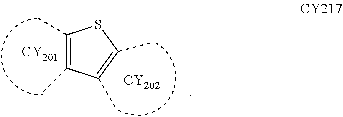

In Formulae CY201 to CY217, R_{10b} and R_{10c} may each independently be the same as described in connection with R₁₀ₐ, ring CY201 to ring CY204 may each independently be a C₃-C₂₀ carbocyclic group or a C₁-C₂₀ heterocyclic group, and at least one hydrogen in Formulae CY201 to CY217 may be unsubstituted or substituted with R₁₀ₐ.

In an embodiment, in Formulae CY201 to CY217, ring CY201 to ring CY204 may each independently be a benzene group, a naphthalene group, a phenanthrene group, or an anthracene group.

In embodiments, the compound represented by Formula 201 and the compound represented by Formula 202 may each independently include at least one of the groups represented by Formulae CY201 to CY203.

In embodiments, the compound represented by Formula 201 may include at least one of the groups represented by Formulae CY201 to CY203 and at least one of the groups represented by Formulae CY204 to CY217.

In embodiments, in Formula 201, xa1 may be 1, R₂₀₁ may be one of the groups represented by Formulae CY201 to CY203, xa2 may be 0, and R₂₀₂ may be one of the groups represented by Formulae CY204 to CY207.

In embodiments, the compound represented by Formula 201 and the compound represented by Formula 202 may each not include the groups represented by Formulae CY201 to CY203.

In embodiments, the compound represented by Formula 201 and the compound represented by Formula 202 may each not include the groups represented by Formulae CY201 to CY203, and may each independently include at least one of the groups represented by Formulae CY204 to CY217.

In embodiments, the compound represented by Formula 201 and the compound represented by Formula 202 may each not include the groups represented by Formulae CY201 to CY217.

In an embodiment, the hole transport region may include one of Compounds HT1 to HT46, m-MTDATA, TDATA, 2-TNATA, NPB(NPD), B-NPB, TPD, Spiro-TPD, Spiro-NPB, methylated NPB, TAPC, HMTPD, 4,4′,4″-tris(N-carbazolyl)triphenylamine (TCTA), polyaniline/dodecylbenzenesulfonic acid (PANI/DBSA), poly(3,4-ethylenedioxythiophene)/poly(4-styrenesulfonate) (PEDOT/PSS), polyaniline/camphor sulfonic acid (PANI/CSA), polyaniline/poly(4-styrenesulfonate) (PANI/PSS), or any combination thereof:

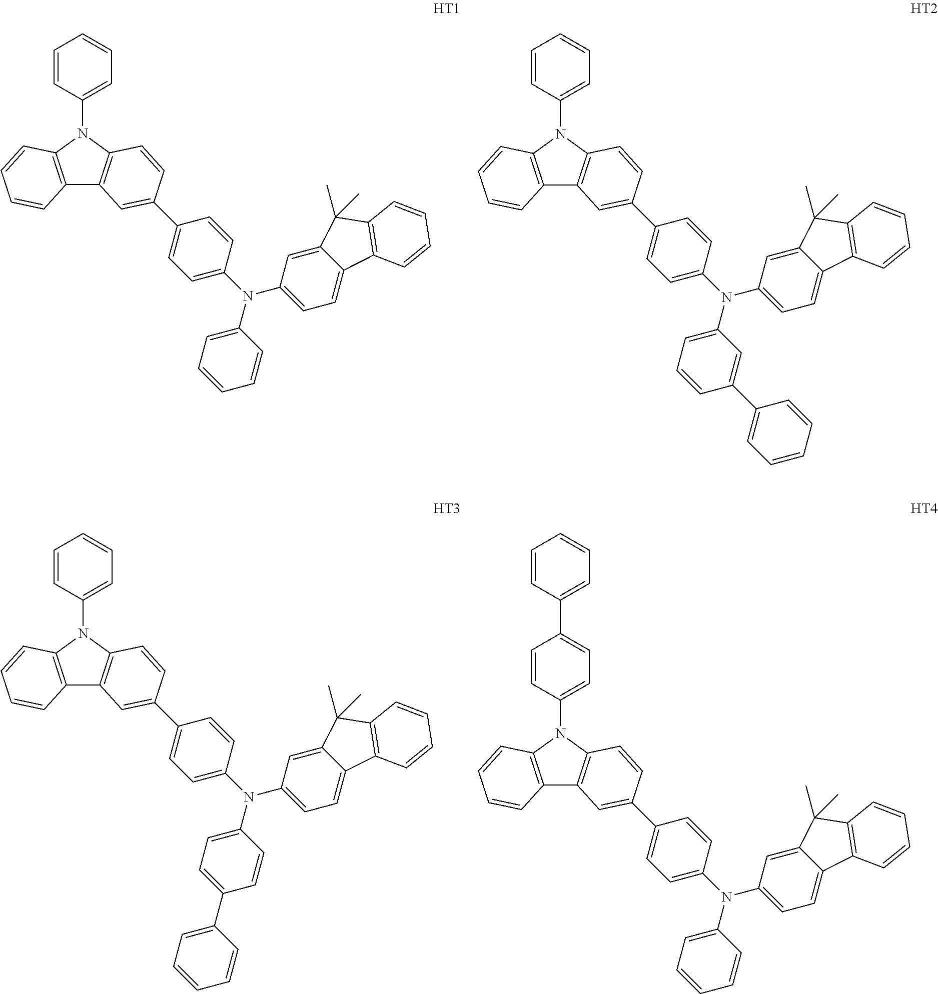 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21 ; CC1(C)c2ccccc2-c2ccc(N(c3ccccc3)c3ccc(-c4ccc5c(c4)c4ccccc4n5-c4ccc(-c5ccccc5)cc4)cc3)cc21]

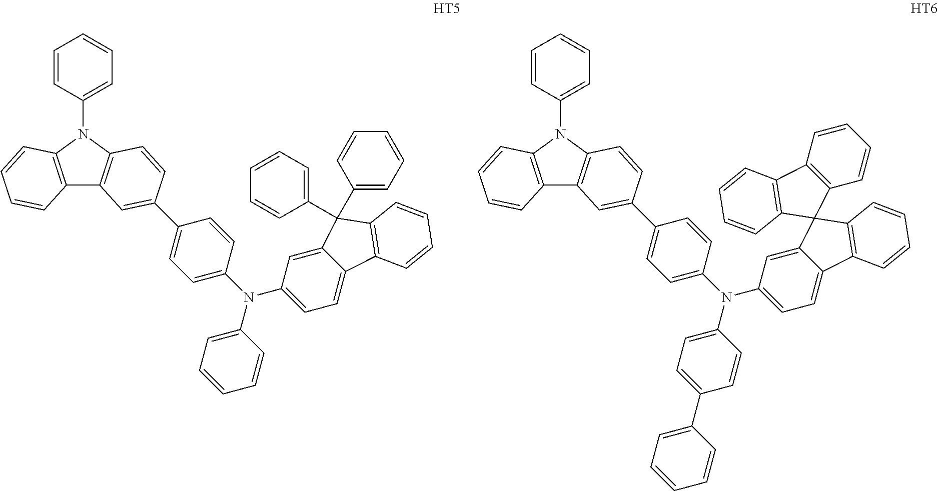 [SMILES: c1ccc(N(c2ccc(-c3ccc4c(c3)c3ccccc3n4-c3ccccc3)cc2)c2ccc3c(c2)C(c2ccccc2)(c2ccccc2)c2ccccc2-3)cc1 ; c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1]

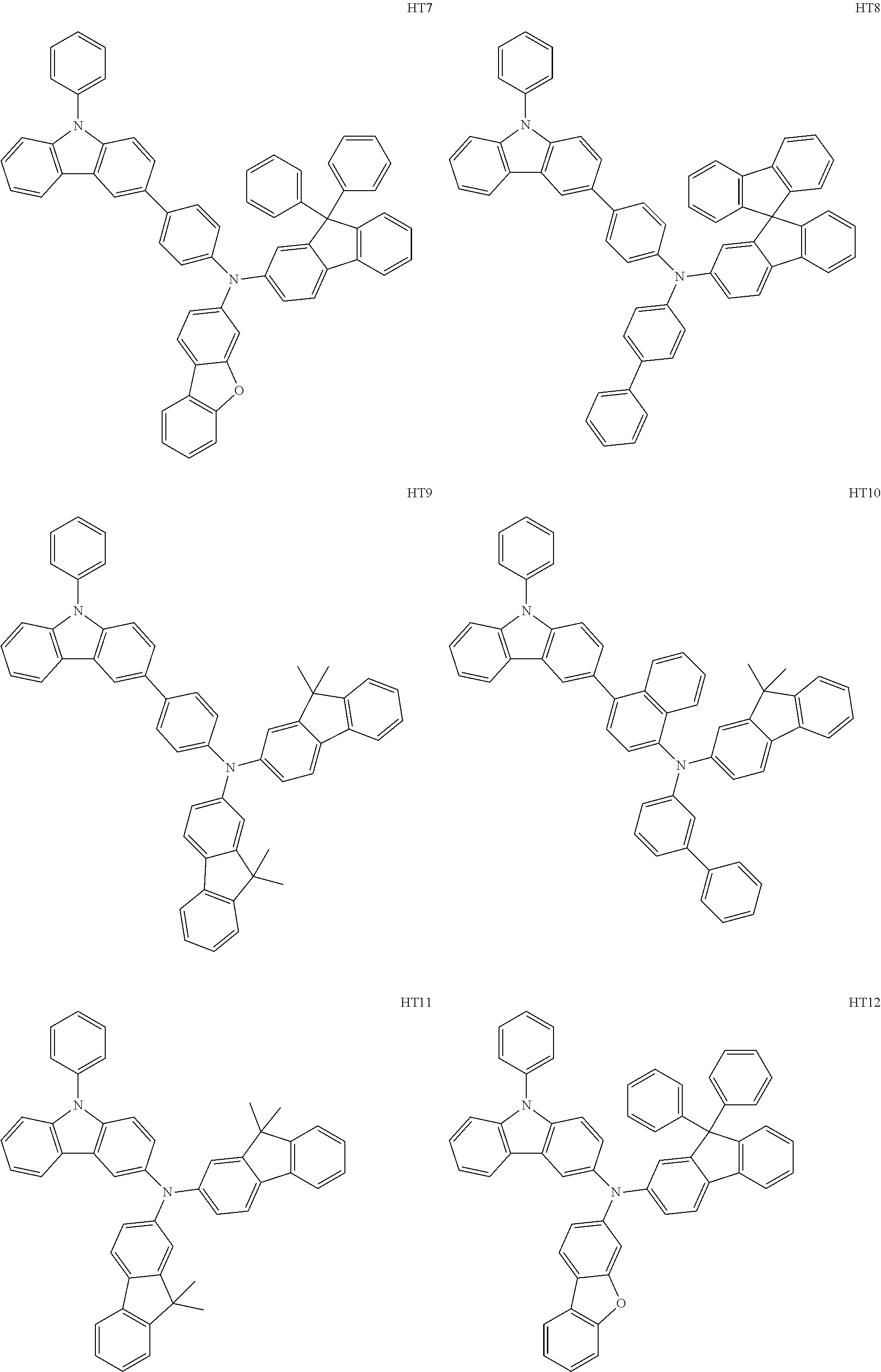

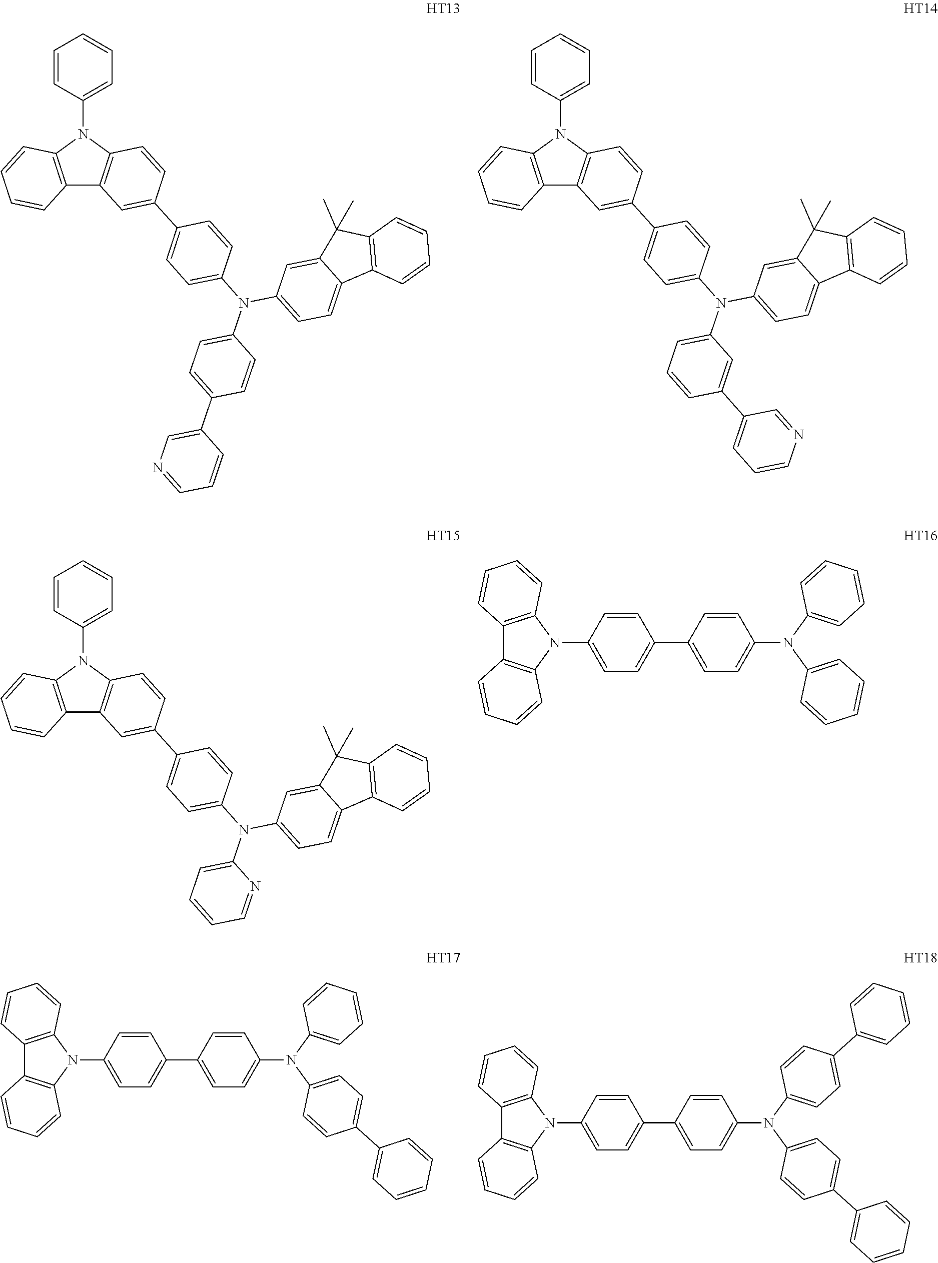

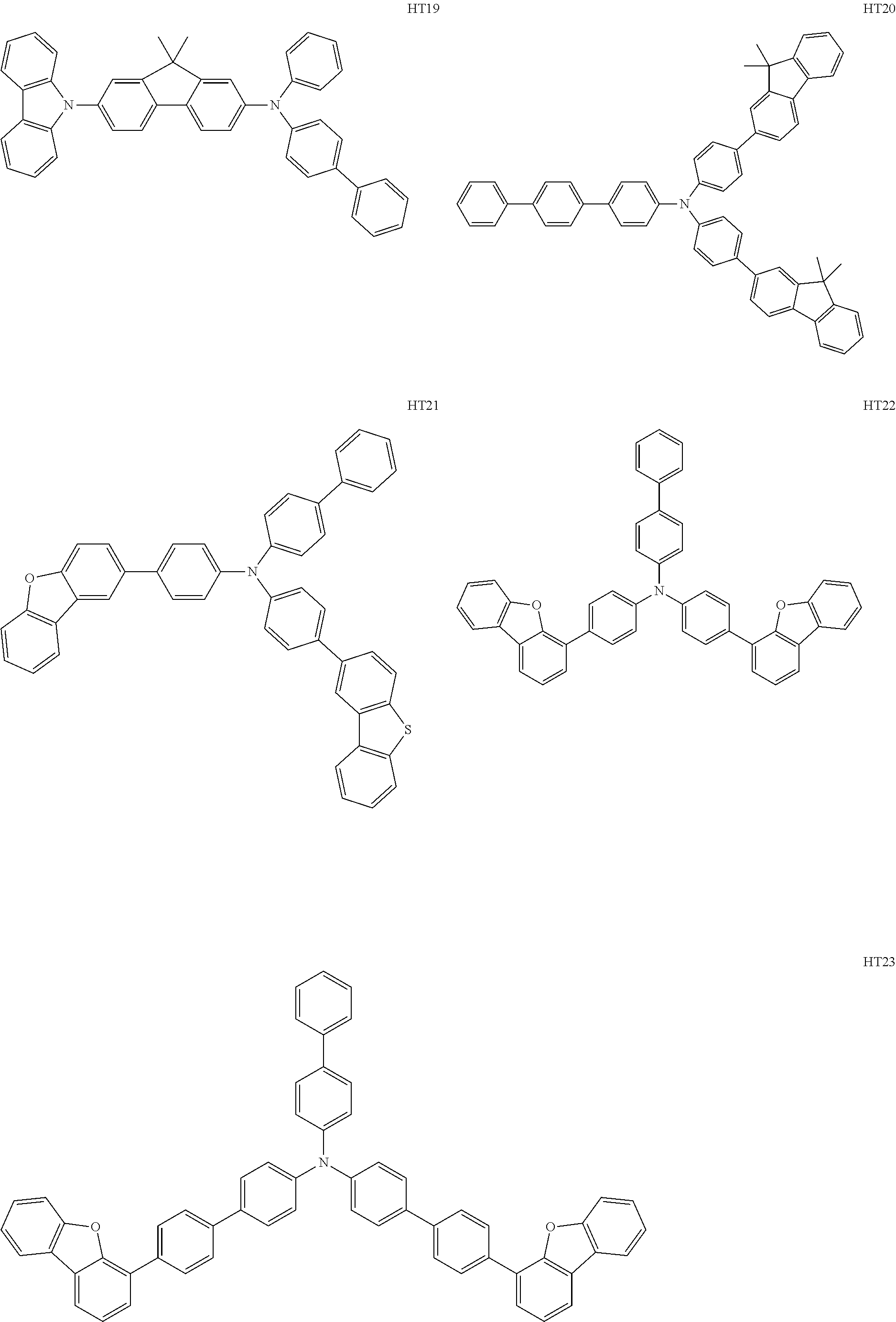 [SMILES: CC1(C)c2cc(N(c3ccccc3)c3ccc(-c4ccccc4)cc3)ccc2-c2ccc(-n3c4ccccc4c4ccccc43)cc21 ; CC1(C)c2ccccc2-c2ccc(-c3ccc(N(c4ccc(-c5ccc(-c6ccccc6)cc5)cc4)c4ccc(-c5ccc6c(c5)C(C)(C)c5ccccc5-6)cc4)cc3)cc21 ; c1ccc(-c2ccc(N(c3ccc(-c4ccc5oc6ccccc6c5c4)cc3)c3ccc(-c4ccc5sc6ccccc6c5c4)cc3)cc2)cc1 ; c1ccc(-c2ccc(N(c3ccc(-c4cccc5c4oc4ccccc45)cc3)c3ccc(-c4cccc5c4oc4ccccc45)cc3)cc2)cc1 ; c1ccc(-c2ccc(N(c3ccc(-c4ccc(-c5cccc6c5oc5ccccc56)cc4)cc3)c3ccc(-c4ccc(-c5cccc6c5oc5ccccc56)cc4)cc3)cc2)cc1]

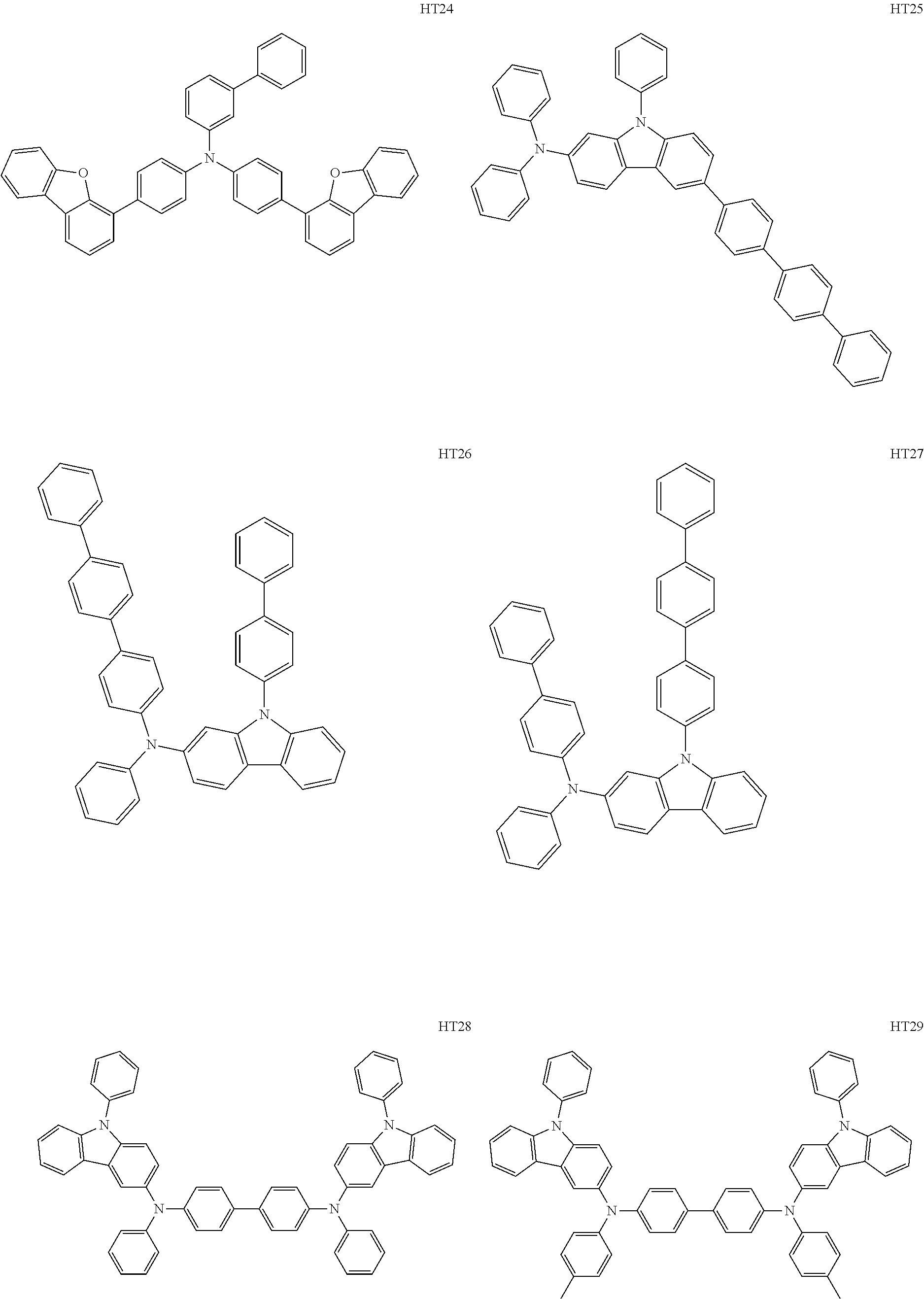

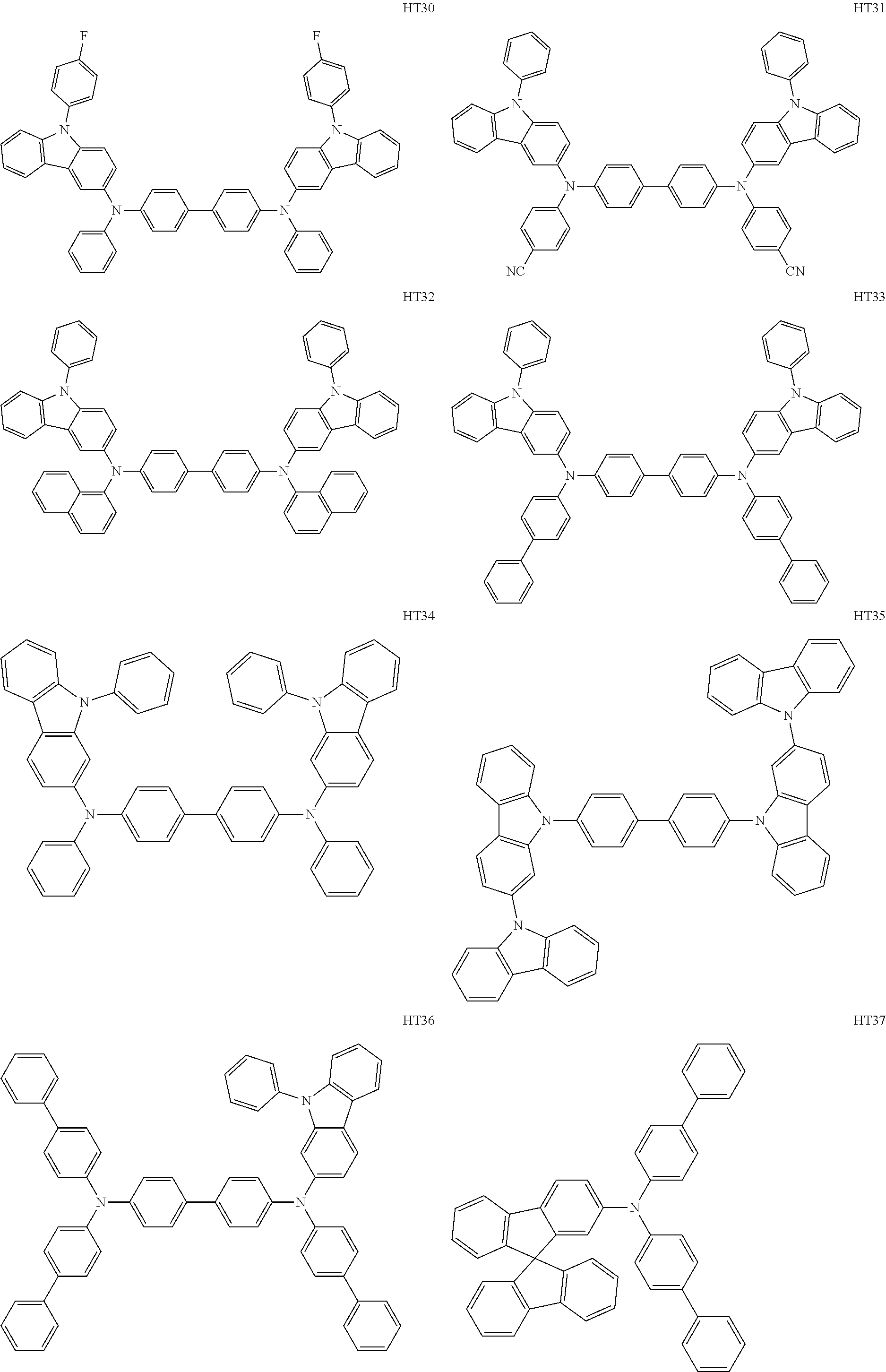

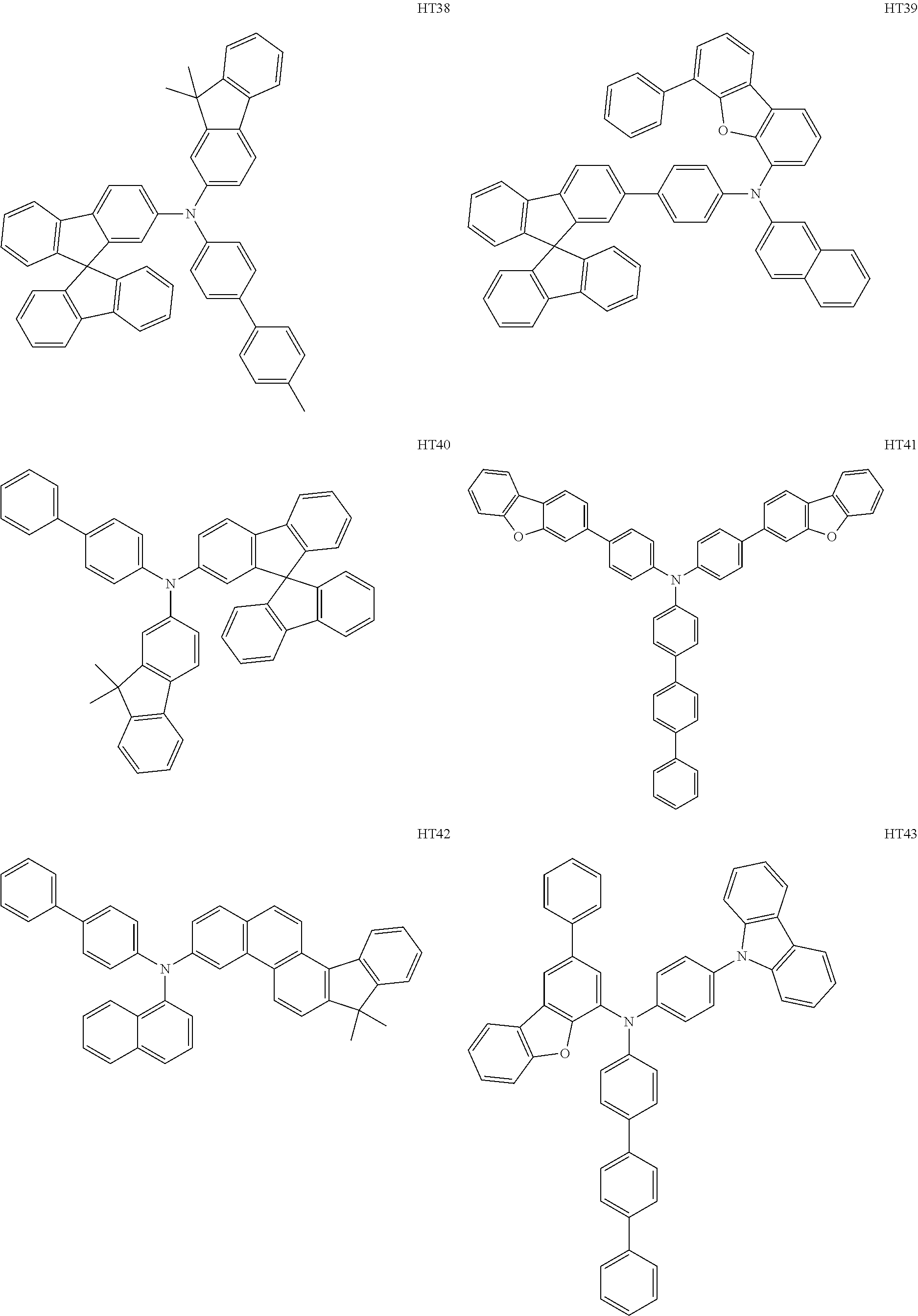

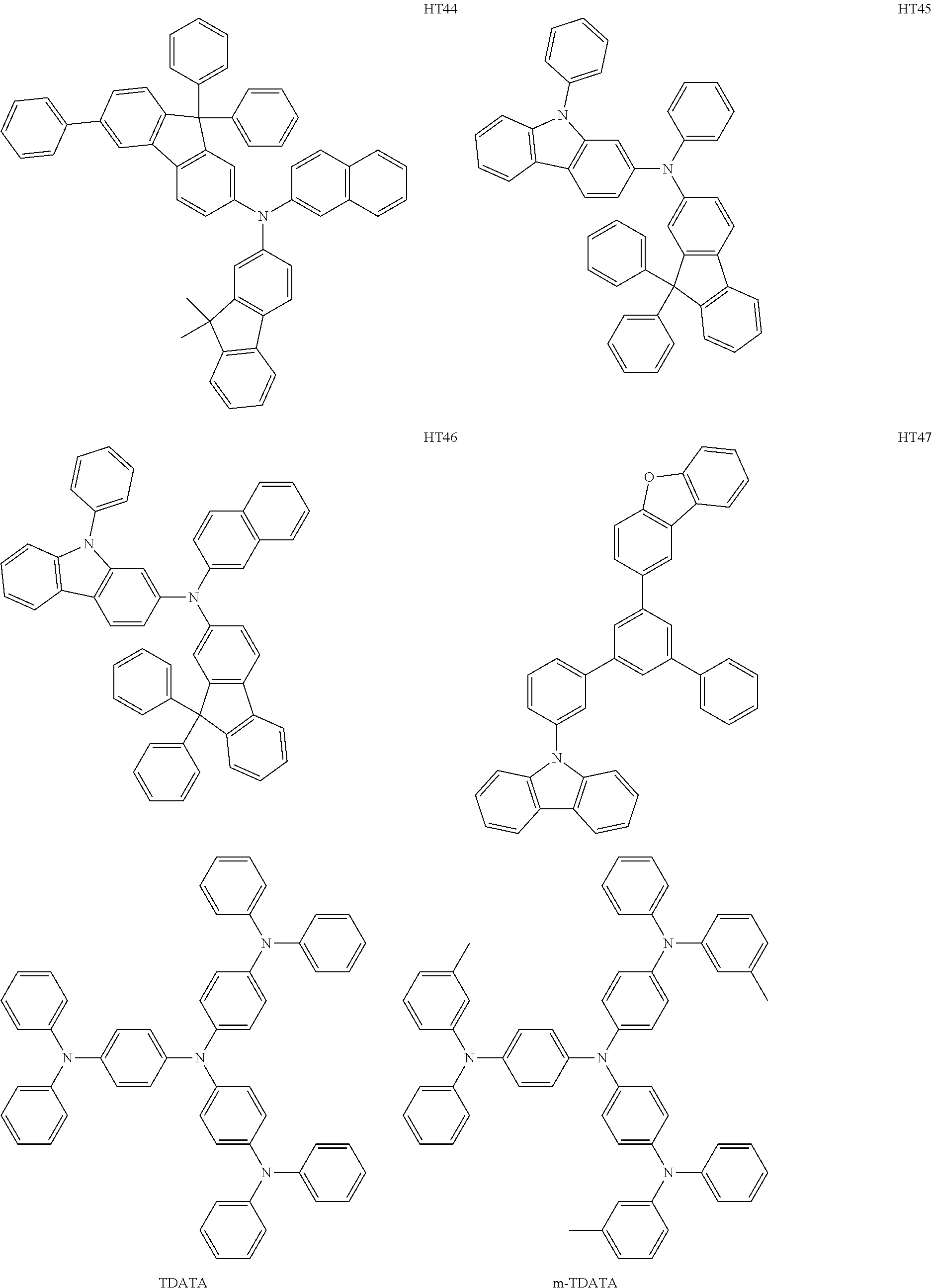

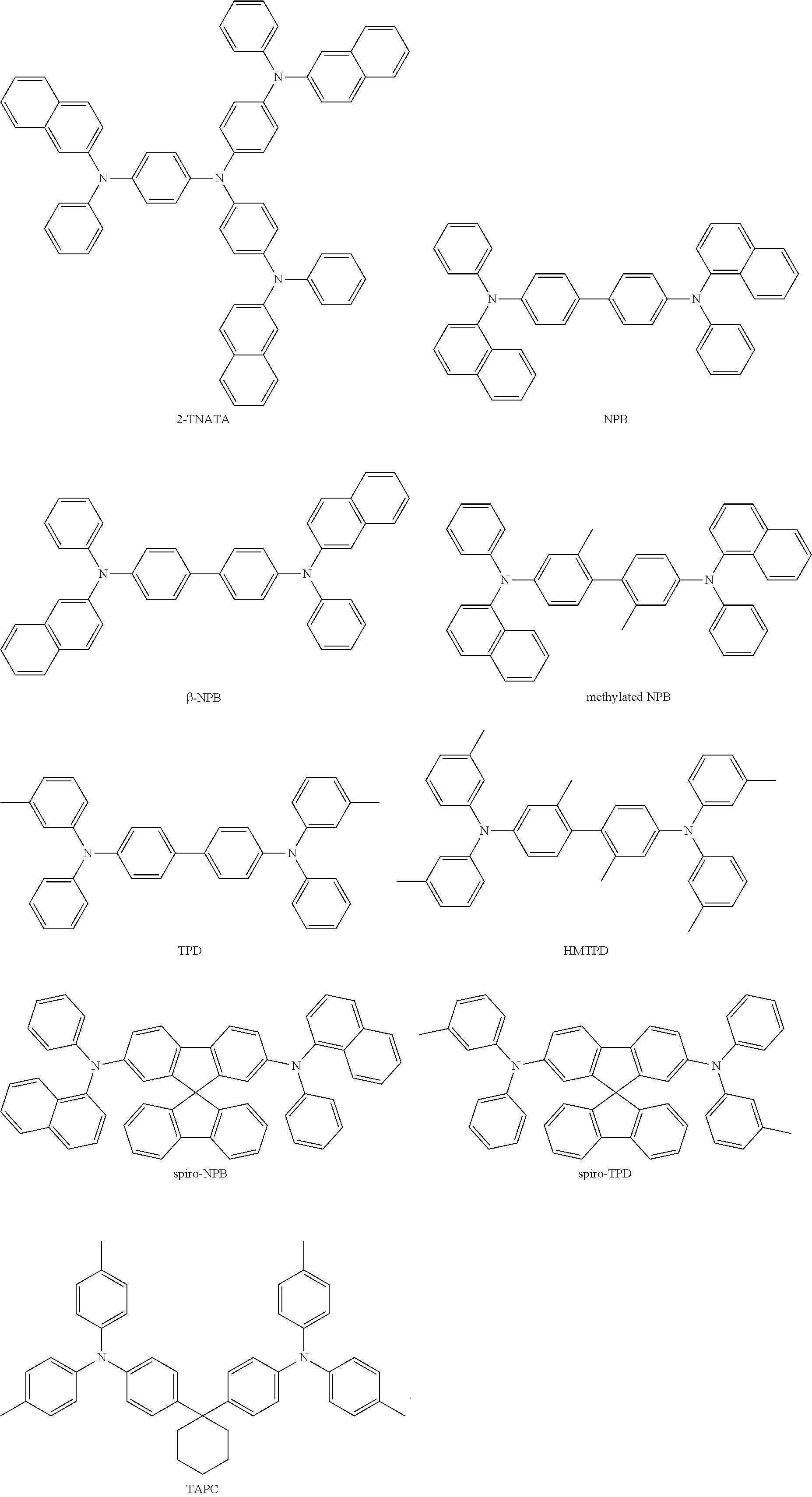

The hole transport region 140 may have a thickness in a range of about 50 Å to about 10,000 Å. For example, the hole transport region may have a thickness in a range of about 100 Å to about 4,000 Å. When the hole transport region 140 includes a hole injection layer, a hole transport layer, or any combination thereof, a thickness of the hole injection layer may be in a range of about 100 Å to about 9,000 Å, for example, and a thickness of the hole transport layer may be in a range of about 50 Å to about 2,000 Å. For example, a thickness of the hole injection layer may be in a range of about 100 Å to about 1,000 Å. For example, a thickness of the hole transport layer may be in a range of about 100 Å to about 1,500 Å. When the thicknesses of the hole transport region 140, the hole injection layer, and the hole transport layer are within these ranges, satisfactory hole transporting characteristics may be obtained without a substantial increase in driving voltage.

The emission auxiliary layer may increase light emission efficiency by compensating for an optical resonance distance according to a wavelength of light emitted from the emission layer, and the electron blocking layer may block the leakage of electrons from the emission layer to the hole transport region. Materials that may be included in the hole transport region may be included in the emission auxiliary layer and the electron blocking layer.

[p-Dopant]

The hole transport region 140 may further include, in addition to the materials as described above, a charge-generation material for the improvement of conductive characteristics. The charge-generation material may be uniformly or non-uniformly dispersed in the hole transport region (for example, in the form of a single layer consisting of a charge-generation material).

The charge-generation material may be, for example, a p-dopant.

In an embodiment, the p-dopant may have a lowest unoccupied molecular orbital (LUMO) energy level equal to or less than about −3.5 eV.

In an embodiment, the p-dopant may include a quinone derivative, a cyano group-containing compound, a compound including element EL1 and element EL2, or any combination thereof.

Examples of a quinone derivative may include TCNQ, F4-TCNQ, and the like.

Examples of a cyano group-containing compound may include HAT-CN, a compound represented by Formula 221, and the like:

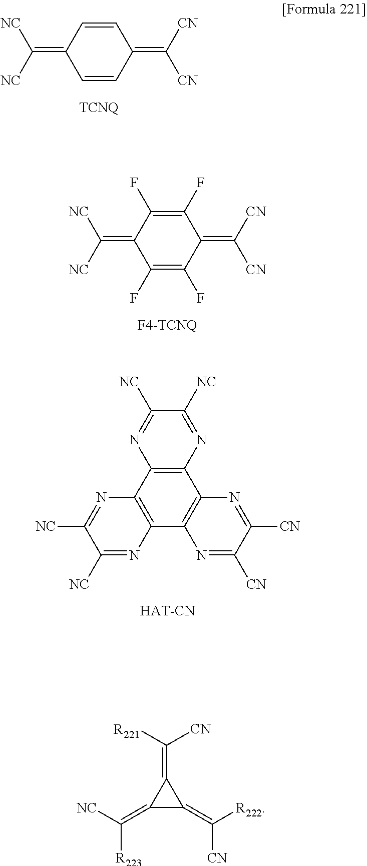

In Formula 221,

R₂₂₁ to R₂₂₃ may each independently be a C₃-C₆₀ carbocyclic group unsubstituted or substituted with at least one R₁₀ₐ or a C₁-C₆₀ heterocyclic group unsubstituted or substituted with at least one R₁₀ₐ, and

at least one of R₂₂₁ to R₂₂₃ may each independently be a C₃-C₆₀ carbocyclic group or a C₁-C₆₀ heterocyclic group, each substituted with: a cyano group; —F; —Cl; —Br; —I; a C₁-C₂₀ alkyl group substituted with a cyano group, —F, —Cl, —Br, —I, or any combination thereof; or any combination thereof.

In the compound including element EL1 and element EL2, element EL1 may be a metal, a metalloid, or any combination thereof, and element EL2 may be a non-metal, a metalloid, or any combination thereof.

Examples of a metal may include: an alkali metal (for example, lithium (Li), sodium (Na), potassium (K), rubidium (Rb), cesium (Cs), etc.); an alkaline earth metal (for example, beryllium (Be), magnesium (Mg), calcium (Ca), strontium (Sr), barium (Ba), etc.); a transition metal (for example, titanium (Ti), zirconium (Zr), hafnium (Hf), vanadium (V), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), etc.); a post-transition metal (for example, zinc (Zn), indium (In), tin (Sn), etc.); a lanthanide metal (for example, lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), etc.); and the like.

Examples of a metalloid may include silicon (Si), antimony (Sb), tellurium (Te), and the like.

Examples of a non-metal may include oxygen (O), a halogen (for example, F, Cl, Br, I, etc.), and the like.

Examples of a compound containing element EL1 and element EL2 may include a metal oxide, a metal halide (e.g., a metal fluoride, a metal chloride, a metal bromide, a metal iodide, etc.), a metalloid halide (e.g., a metalloid fluoride, a metalloid chloride, a metalloid bromide, a metalloid iodide, etc.), a metal telluride, or any combination thereof.

Examples of a metal oxide may include a tungsten oxide (e.g., WO, W₂O₃, WO₂, WO₃, W₂O₅, etc.), a vanadium oxide (e.g., VO, V₂O₃, VO₂, V₂O₅, etc.), a molybdenum oxide (e.g., MoO, Mo₂O₃, MoO₂, MoO₃, Mo₂O₅, etc.), a rhenium oxide (e.g., ReO₃, etc.), and the like.

Examples of a metal halide may include an alkali metal halide, an alkaline earth metal halide, a transition metal halide, a post-transition metal halide, a lanthanide metal halide, and the like.

Examples of an alkali metal halide may include LiF, NaF, KF, RbF, CsF, LiCl, NaCl, KCl, RbCl, CsCl, LiBr, NaBr, KBr, RbBr, CsBr, LiI, NaI, KI, RbI, CsI, and the like.

Examples of an alkaline earth metal halide may include BeF₂, MgF₂, CaF₂, SrF₂, BaF₂, BeCl₂, MgCl₂, CaCl₂), SrCl₂, BaCl₂, BeBr₂, MgBr₂, CaBr₂, SrBr₂, BaBr₂, BeI₂, MgI₂, CaI₂, SrI₂, BaI₂, and the like.

Examples of a transition metal halide may include a titanium halide (e.g., TiF₄, TiCl₄, TiBr₄, TiI₄, etc.), a zirconium halide (e.g., ZrF₄, ZrCl₄, ZrBr₄, ZrI₄, etc.), a hafnium halide (e.g., HfF₄, HfCl₄, HfBr₄, HfI₄, etc.), a vanadium halide (e.g., VF₃, VCl₃, VBr₃, VI₃, etc.), a niobium halide (e.g., NbF₃, NbCl₃, NbBr₃, NbI₃, etc.), a tantalum halide (e.g., TaF₃, TaCl₃, TaBr₃, TaIs, etc.), a chromium halide (e.g., CrF₃, CrCl₃, CrBr₃, CrIs, etc.), a molybdenum halide (e.g., MoF₃, MoCl₃, MoBr₃, MoIs, etc.), a tungsten halide (e.g., WF₃, WCl₃, WBr₃, WIs, etc.), a manganese halide (e.g., MnF₂, MnCl₂, MnBr₂, MnI₂, etc.), a technetium halide (e.g., TcF₂, TcCl₂, TcBr₂, TcI₂, etc.), a rhenium halide (e.g., ReF₂, ReCl₂, ReBr₂, ReI₂, etc.), an iron halide (e.g., FeF₂, FeCl₂, FeBr₂, FeI₂, etc.), a ruthenium halide (e.g., RuF₂, RuCl₂, RuBr₂, RuI₂, etc.), an osmium halide (e.g., OsF₂, OsCl₂, OsBr₂, OsI₂, etc.), a cobalt halide (e.g., CoF₂, CoCl₂, CoBr₂, CoI₂, etc.), a rhodium halide (e.g., RhF₂, RhCl₂, RhBr₂, RhI₂, etc.), an iridium halide (e.g., IrF₂, IrCl₂, IrBr₂, IrI₂, etc.), a nickel halide (e.g., NiF₂, NiCl₂, NiBr₂, NiI₂, etc.), a palladium halide (e.g., PdF₂, PdCl₂, PdBr₂, PdI₂, etc.), a platinum halide (e.g., PtF₂, PtCl₂, PtBr₂, PtI₂, etc.), a copper halide (e.g., CuF, CuCl, CuBr, CuI, etc.), a silver halide (e.g., AgF, AgCl, AgBr, AgI, etc.), a gold halide (e.g., AuF, AuCl, AuBr, AuI, etc.), and the like.

Examples of a post-transition metal halide may include a zinc halide (e.g., ZnF₂, ZnCl₂, ZnBr₂, ZnI₂, etc.), an indium halide (e.g., InI₃, etc.), a tin halide (e.g., SnI₂, etc.), and the like.

Examples of a lanthanide metal halide may include YbF, YbF₂, YbF₃, SmF₃, YbCl, YbCl₂, YbCl₃ SmCl₃, YbBr, YbBr₂, YbBr₃ SmBr₃, YbI, YbI₂, YbI₃, SmI₃, and the like.

Examples of a metalloid halide may include an antimony halide (e.g., SbCl₅, etc.) and the like.

Examples of a metal telluride may include an alkali metal telluride (e.g., Li₂Te, Na₂Te, K₂Te, Rb₂Te, Cs₂Te, etc.), an alkaline earth metal telluride (e.g., BeTe, MgTe, CaTe, SrTe, BaTe, etc.), a transition metal telluride (e.g., TiTe₂, ZrTe₂, HfTe₂, V₂Te₃, Nb₂Te₃, Ta₂Te₃, Cr₂Te₃, Mo₂Te₃, W₂Te₃, MnTe, ToTe, ReTe, FeTe, RuTe, OsTe, CoTe, RhTe, IrTe, NiTe, PdTe, PtTe, Cu₂Te, CuTe, Ag₂Te, AgTe, AuzTe, etc.), a post-transition metal telluride (e.g., ZnTe, etc.), a lanthanide metal telluride (e.g., LaTe, CeTe, PrTe, NdTe, PmTe, EuTe, GdTe, TbTe, DyTe, HoTe, ErTe, TmTe, YbTe, LuTe, etc.), and the like.

### [Second Electrode 150]

The second electrode 150 is arranged on the hole transport region 140. In an embodiment, the second electrode 150 may be an anode,

The second electrode 150 may include Li, Ag, Mg, Al, Al-Li, Ca, Mg-In, Mg-Ag, Yb, Ag-Yb, ITO, IZO, or any combination thereof. The second electrode 150 may be a transmissive electrode, a semi-transmissive electrode, or a reflective electrode.

The second electrode 150 may have a single layer structure or a multi-layer structure.

### [Capping Layer]

The light-emitting device 10 may include a first capping layer outside the first electrode 110 and/or a second capping layer outside the second electrode 150. In embodiments, the light-emitting device 10 may have a structure in which the first capping layer, the first electrode 110, the organic layer 160, and the second electrode 150 are stacked in the stated order, a structure in which the first electrode 110, the organic layer 160, the second electrode 150, and the second capping layer are stacked in the stated order, or a structure in which the first capping layer, the first electrode 110, the organic layer 160, the second electrode 150, and the second capping layer are stacked in the stated order.

Light generated in an emission layer of the organic layer 160 of the light-emitting device 10 may be extracted toward the outside through the first electrode 110, which may be a semi-transmissive electrode or a transmissive electrode, and through the first capping layer. Light generated in an emission layer of the organic layer 160 of the light-emitting device 10 may be extracted toward the outside through the second electrode 150, which may be a semi-transmissive electrode or a transmissive electrode, and through the second capping layer.

The first capping layer and the second capping layer may each increase external emission efficiency according to the principle of constructive interference. Accordingly, the light extraction efficiency of the light-emitting device 10 is increased, so that the luminescence efficiency of the light-emitting device 10 may be improved.

The first capping layer and the second capping layer may each include a material having a refractive index equal to or greater than about 1.6 (with respect to a wavelength of about 589 nm).

The first capping layer and the second capping layer may each independently be an organic capping layer including an organic material, an inorganic capping layer including an inorganic material, or an organic-inorganic composite capping layer including an organic material and an inorganic material.

At least one of the first capping layer and the second capping layer may each independently include a carbocyclic compound, a heterocyclic compound, an amine group-containing compound, a porphine derivative, a phthalocyanine derivative, a naphthalocyanine derivative, an alkali metal complex, an alkaline earth metal complex, or any combination thereof. The carbocyclic compound, the heterocyclic compound, and the amine group-containing compound may optionally be substituted with a substituent including O, N, S, Se, Si, F, Cl, Br, I, or any combination thereof. In an embodiment, at least one of the first capping layer and the second capping layer may each independently include an amine group-containing compound.

In embodiments, at least one of the first capping layer and the second capping layer may each independently include a compound represented by Formula 201, a compound represented by Formula 202, or any combination thereof.

In embodiments, at least one of the first capping layer and the second capping layer may each independently include one of Compounds HT28 to HT33, one of Compounds CP1 to CP6, β-NPB, or any combination thereof:

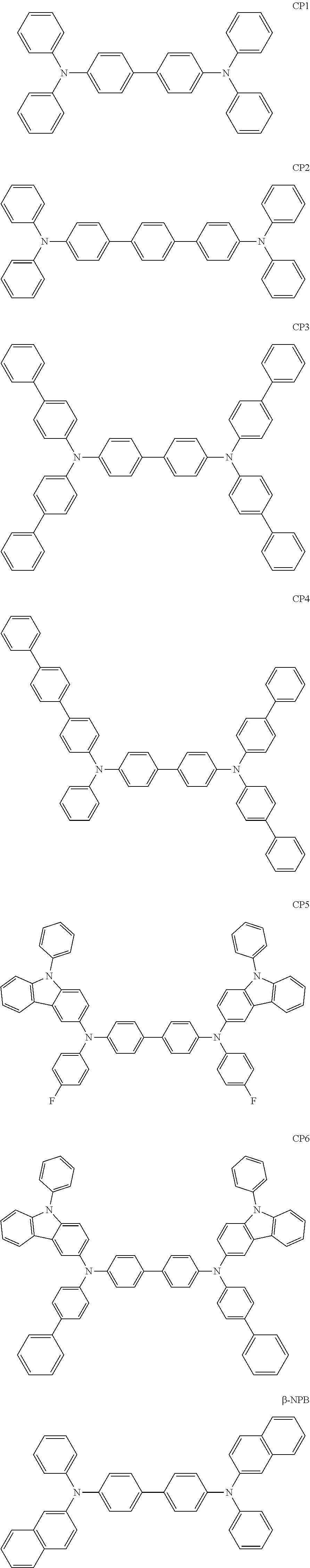

### [Tandem Device]

A light-emitting device according to another embodiment may include:

a first electrode on a substrate;

a second electrode facing the first electrode;

m emission units between the first electrode and the second electrode; and

m−1 charge generation layers, each arranged between two neighboring emission units among the m emission units and each including an n-type charge generation layer and a p-type charge generation layer.

In an embodiment, the first electrode may be a cathode, and the second electrode may be an anode.

The m emission units may each include an electron transport region, an emission layer, and a hole transport region that are sequentially arranged from the first electrode. A detailed description of the electron transport region, the emission layer, and the hole transport region may be the same as described herein.

In embodiments, m may be an integer of 2 or more.

For example, when m is 2, a cathode, a first emission unit, a first charge generation unit, a second emission unit, and an anode may be sequentially arranged. The first emission unit may emit first-color light, and the second emission unit may emit second-color light, wherein a maximum emission wavelength of the first-color light and a maximum emission wavelength of the second-color light may be identical to or different from each other.

As another example, when m is 3, a cathode, a first emission unit, a first charge generation unit, a second emission unit, a second charge generation unit, a third emission unit, and an anode may be sequentially arranged. The first emission unit may emit first-color light, the second emission unit may emit second-color light, and the third emission unit may emit third-color light, wherein a maximum emission wavelength of the first-color light, a maximum emission wavelength of the second-color light, and a maximum emission wavelength of the third-color light may be identical to or different from one another.

As another example, when m is 4, a cathode, a first emission unit, a first charge generation unit, a second emission unit, a second charge generation unit, a third emission unit, a third charge generation unit, a fourth emission unit, and an anode may be sequentially arranged. The first emission unit may emit first-color light, the second emission unit may emit second-color light, the third emission unit may emit third-color light, and the fourth emission unit may emit fourth-color light, wherein a maximum emission wavelength of the first-color light, a maximum emission wavelength of the second-color light, a maximum emission wavelength of the third-color light, and a maximum emission wavelength of the fourth color light may be identical to or different from one another.

### [Electronic Apparatus]

The light-emitting device may be included in various electronic apparatuses. For example, an electronic apparatus including the light-emitting device may be a light-emitting apparatus, an authentication apparatus, or the like.

The electronic apparatus (e.g., a light-emitting apparatus) may further include, in addition to the light-emitting device, a color filter, a color conversion layer, or a color filter and a color conversion layer. The color filter and/or the color conversion layer may be arranged in at least one traveling direction of light emitted from the light-emitting device. For example, the light emitted from the light-emitting device may be blue light or white light. A detailed description of the light-emitting device may be the same as described herein. In an embodiment, the color conversion layer may include quantum dots. The quantum dots may be, for example, the quantum dots as described herein.

The electronic apparatus may include a first substrate. The first substrate may include subpixels, the color filter may include color filter areas respectively corresponding to the subpixels, and the color conversion layer may include color conversion areas respectively corresponding to the subpixels.

A pixel-defining film may be arranged between the subpixels to define each subpixel.

The color filter may further include color filter areas and light-shielding patterns arranged between the color filter areas, and the color conversion layer may further include color conversion areas and light-shielding patterns arranged between the color conversion areas.

The color filter areas (or the color conversion areas) may include a first area emitting first color light, a second area emitting second color light, and/or a third area emitting third color light, wherein the first color light, the second color light, and/or the third color light may have different maximum emission wavelengths from one another. For example, the first color light may be red light, the second color light may be green light, and the third color light may be blue light. In an embodiment, the color filter areas (or the color conversion areas) may include quantum dots. For example, the first area may include red quantum dots, the second area may include green quantum dots, and the third area may not include quantum dots. A detailed description of the quantum dots may be the same as described herein. The first area, the second area, and/or the third area may each further include a scatterer.

In an embodiment, the light-emitting device may emit first light, the first area may absorb the first light to emit first-first color light, the second area may absorb the first light to emit second-first color light, and the third area may absorb the first light to emit third-first color light. The first-first color light, the second-first color light, and the third-first color light may have different maximum emission wavelengths from one another. For example, the first light may be blue light, the first-first color light may be red light, the second-first color light may be green light, and the third-first color light may be blue light.

The electronic apparatus may further include a thin-film transistor, in addition to the aforementioned light-emitting device. The thin-film transistor may include a source electrode, a drain electrode, and an active layer, wherein any one of the source electrode and the drain electrode may be electrically connected to any one of the cathode and the anode of the light-emitting device.

The thin-film transistor may further include a gate electrode, a gate insulating film, and the like.

The active layer may include crystalline silicon, amorphous silicon, an organic semiconductor, an oxide semiconductor, or the like.

The electronic apparatus may further include a sealing portion for sealing the light-emitting device. The sealing portion may be arranged between the color filter and/or the color conversion layer and the light-emitting device. The sealing portion allows light from the light-emitting device to be extracted to the outside, and simultaneously prevents ambient air and moisture from penetrating into the light-emitting device. The sealing portion may be a sealing substrate including a transparent glass substrate or a plastic substrate. The sealing portion may be a thin-film encapsulation layer including at least one of an organic layer and/or an inorganic layer. When the sealing portion is a thin film encapsulation layer, the electronic apparatus may be flexible.

Various functional layers may be further included on the sealing portion, in addition to the color filter and/or the color conversion layer, according to a use of the electronic apparatus. Examples of a functional layer may include a touch screen layer, a polarizing layer, and the like. The touch screen layer may be a pressure-sensitive touch screen layer, a capacitive touch screen layer, or an infrared touch screen layer.

The authentication apparatus may further include, in addition to the light-emitting device as described above, a biometric information collector. The authentication apparatus may be, for example, a biometric authentication apparatus that authenticates an individual by using biometric information of a living body (e.g., fingertips, pupils, etc.).

The electronic apparatus may be applied to various displays, light sources, lighting, personal computers (e.g., mobile personal computers), mobile phones, digital cameras, electronic organizers, electronic dictionaries, electronic game machines, medical instruments (e.g., electronic thermometers, sphygmomanometers, blood glucose meters, pulse measurement devices, pulse wave measurement devices, electrocardiogram displays, ultrasonic diagnostic devices, or endoscope displays), fish finders, various measuring instruments, meters (e.g., meters for a vehicle, an aircraft, and a vessel), projectors, and the like.

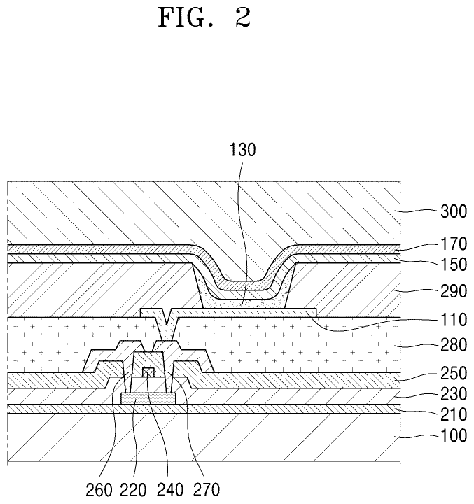

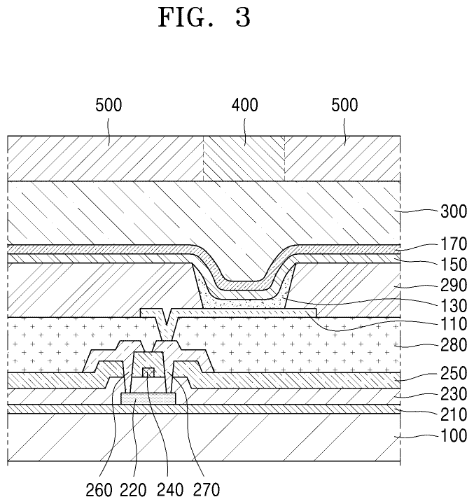

### [Description of FIGS. 2 and 3]

FIG. 2 is a schematic cross-sectional view of an electronic apparatus according to an embodiment.

The electronic apparatus (e.g., a light-emitting apparatus) of FIG. 2 includes a substrate 100, a thin-film transistor (TFT), a light-emitting device, and an encapsulation portion 300 that seals the light-emitting device.

The substrate 100 may be a flexible substrate, a glass substrate, or a metal substrate. A buffer layer 210 may be arranged on the substrate 100. The buffer layer 210 may prevent penetration of impurities through the substrate 100 and may provide a flat surface on the substrate 100.

A TFT may be arranged on the buffer layer 210. The TFT may include an active layer 220, a gate electrode 240, a source electrode 260, and a drain electrode 270.

The active layer 220 may include an inorganic semiconductor, such as silicon or polysilicon, an organic semiconductor, or an oxide semiconductor, and may include a source region, a drain region, and a channel region.

A gate insulating film 230 for insulating the active layer 220 from the gate electrode 240 may be arranged on the active layer 220, and the gate electrode 240 may be arranged on the gate insulating film 230.

An interlayer insulating film 250 may be arranged on the gate electrode 240. The interlayer insulating film 250 may be arranged between the gate electrode 240 and the source electrode 260 to insulate the gate electrode 240 from the source electrode 260 and between the gate electrode 240 and the drain electrode 270 to insulate the gate electrode 240 from the drain electrode 270.

The source electrode 260 and the drain electrode 270 may be arranged on the interlayer insulating film 250. The interlayer insulating film 250 and the gate insulating film 230 may be formed to expose a source region and a drain region of the active layer 220, and the source electrode 260 and the drain electrode 270 may respectively contact the exposed portions of the source region and the drain region of the active layer 220.

The TFT may be electrically connected to a light-emitting device to drive the light-emitting device, and may be covered and protected by a passivation layer 280. The passivation layer 280 may include an inorganic insulating film, an organic insulating film, or any combination thereof. A light-emitting device may be provided on the passivation layer 280. The light-emitting device includes a first electrode 110 (e.g., a cathode), an organic layer 160, and a second electrode 150 (e.g., an anode).

The first electrode 110 may be arranged on the passivation layer 280. The passivation layer 280 may not completely cover the drain electrode 270 and may expose a portion of the drain electrode 270. The first electrode 110 may be connected (e.g., electrically connected) to the exposed portion of the drain electrode 270.

A pixel defining layer 290 including an insulating material may be arranged on the first electrode 110. The pixel-defining film 290 may expose a region of the first electrode 110, and the organic layer 160 may be formed in the exposed region of the first electrode 110. The pixel defining layer 290 may be a polyimide-based organic film or a polyacrylic-based organic film. Although not shown in FIG. 2, at least some layers of the organic layer 160 may extend beyond the upper portion of the pixel defining layer 290 to be provided in the form of a common layer.

The second electrode 150 may be arranged on the organic layer 160, and a capping layer 170 may be further included on the second electrode 150. The capping layer 170 may be formed to cover the second electrode 150.

The encapsulation portion 300 may be arranged on the capping layer 170. The encapsulation portion 300 may be arranged on a light-emitting device to protect the light-emitting device from moisture and/or oxygen. The encapsulation portion 300 may include: an inorganic film including silicon nitride (SiNₓ), silicon oxide (SiOₓ), indium tin oxide, indium zinc oxide, or any combination thereof; an organic film including polyethylene terephthalate, polyethylene naphthalate, polycarbonate, polyimide, polyethylene sulfonate, polyoxymethylene, polyarylate, hexamethyldisiloxane, an acrylic resin (e.g., polymethyl methacrylate, polyacrylic acid, etc.), an epoxy-based resin (e.g., aliphatic glycidyl ether (AGE), etc.), or any combination thereof; or any combination of the inorganic films and the organic films.

FIG. 3 is a schematic cross-sectional view of an electronic apparatus according to another embodiment.

The electronic apparatus (e.g., a light-emitting apparatus) of FIG. 3 may differ from the electronic apparatus of FIG. 2, at least in that a light-shielding pattern 500 and a functional region 400 are further included on the encapsulation portion 300. The functional region 400 may be a color filter area, a color conversion area, or a combination of the color filter area and the color conversion area. In an embodiment, a light-emitting device included in the light-emitting apparatus of FIG. 3 may be a tandem light-emitting device.

### [Manufacturing Method]

Layers constituting the hole transport region, the emission layer, and the layers constituting the electron transport region may be formed in a selected region by using various methods such as vacuum deposition, spin coating, casting, Langmuir-Blodgett (LB) deposition, ink-jet printing, laser-printing, laser-induced thermal imaging, and the like.

When layers constituting the hole transport region, the emission layer, and the layers constituting the electron transport region are formed by vacuum deposition, the deposition may be performed at a deposition temperature in a range of about 100° C. to about 500° C., at a vacuum degree in a range of about 10-8 torr to about 10-3 torr, and at a deposition speed in a range of about 0.01 Å/sec to about 100 Å/sec, depending on a material to be included in a layer to be formed and the structure of a layer to be formed.

### Definitions of Terms

The term “C₃-C₆₀ carbocyclic group” as used herein may be a cyclic group consisting of carbon atoms as the only ring-forming atoms and having three to sixty carbon atoms. The term “C₁-C₆₀ heterocyclic group” as used herein may be a cyclic group that has one to sixty carbon atoms and further has, in addition to a carbon atom, at least one heteroatom as a ring-forming atom. The C₃-C₆₀ carbocyclic group and the C₁-C₆₀ heterocyclic group may each be a monocyclic group consisting of one ring or a polycyclic group in which two or more rings are condensed with each other. For example, the number of ring-forming atoms in a C₁-C₆₀ heterocyclic group may be from 3 to 61.

The term “cyclic group” as used herein may be a C₃-C₆₀ carbocyclic group or a C₁-C₆₀ heterocyclic group.

The term “π electron-rich C₃-C₆₀ cyclic group” as used herein may be a cyclic group that has 3 to 60 carbon atoms and may not include *—N═*′ as a ring-forming moiety. The term “π electron-deficient nitrogen-containing C₁-C₆₀ cyclic group” as used herein may be a heterocyclic group that has 1 to 60 carbon atoms and may include *—N═*′ as a ring-forming moiety.

In embodiments,

a C₃-C₆₀ carbocyclic group may be a T1 group or a group in which two or more T1 groups are condensed with each other (for example, a cyclopentadiene group, an adamantane group, a norbornane group, a benzene group, a pentalene group, a naphthalene group, an azulene group, an indacene group, an acenaphthylene group, a phenalene group, a phenanthrene group, an anthracene group, a fluoranthene group, a triphenylene group, a pyrene group, a chrysene group, a perylene group, a pentaphene group, a heptalene group, a naphthacene group, a picene group, a hexacene group, a pentacene group, a rubicene group, a coronene group, an ovalene group, an indene group, a fluorene group, a spiro-bifluorene group, a benzofluorene group, an indenophenanthrene group, or an indenoanthracene group),

a C₁-C₆₀ heterocyclic group may be a T2 group, a group in which at least two T2 groups are condensed with each other, or a group in which at least one T2 group and at least one T1 group are condensed with each other (for example, a pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, or the like),

a π electron-rich C₃-C₆₀ cyclic group may be a T1 group, a group in which two or more T1 groups are condensed with each other, a T3 group, a group in which two or more T3 groups are condensed with each other, or a group in which at least one T3 group and at least one T1 group are condensed with each other (for example, a C₃-C₆₀ carbocyclic group, a 1H-pyrrole group, a silole group, a borole group, a 2H-pyrrole group, a 3H-pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, etc.), and

a π electron-deficient nitrogen-containing C₁-C₆₀ cyclic group may be a T4 group, a group in which at least two T4 groups are condensed with each other, a group in which at least one T4 group and at least one T1 group are condensed with each other, a group in which at least one T4 group and at least one T3 group are condensed with each other, or a group in which at least one T4 group, at least one T1 group, and at least one T3 group are condensed with one another (for example, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, and the like), wherein

the T1 group may be a cyclopropane group, a cyclobutane group, a cyclopentane group, a cyclohexane group, a cycloheptane group, a cyclooctane group, a cyclobutene group, a cyclopentene group, a cyclopentadiene group, a cyclohexene group, a cyclohexadiene group, a cycloheptene group, an adamantane group, a norbornane (or bicyclo[2.2.1]heptane) group, a norbornene group, a bicyclo[1.1.1]pentane group, a bicyclo[2.1.1]hexane group, a bicyclo[2.2.2]octane group, or a benzene group,

the T2 group may be a furan group, a thiophene group, a 1H-pyrrole group, a silole group, a borole group, a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, a tetrazine group, a pyrrolidine group, an imidazolidine group, a dihydropyrrole group, a piperidine group, a tetrahydropyridine group, a dihydropyridine group, a hexahydropyrimidine group, a tetrahydropyrimidine group, a dihydropyrimidine group, a piperazine group, a tetrahydropyrazine group, a dihydropyrazine group, a tetrahydropyridazine group, or a dihydropyridazine group,

the T3 group may be a furan group, a thiophene group, a 1H-pyrrole group, a silole group, or a borole group, and

the T4 group may be a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, or a tetrazine group.

The terms “cyclic group,” “C₃-C₆₀ carbocyclic group,” “C₁-C₆₀ heterocyclic group,” “π electron-rich C₃-C₆₀ cyclic group,” and “π electron-deficient nitrogen-containing C₁-C₆₀ cyclic group” as used herein may each be a group condensed to any cyclic group, a monovalent group, or a polyvalent group (for example, a divalent group, a trivalent group, a tetravalent group, or the like) according to the structure of a formula for which the corresponding term is used. In an embodiment, a “benzene group” may be a benzo group, a phenyl group, a phenylene group, or the like, which may be readily understood by one of ordinary skill in the art according to the structure of a formula including the “benzene group.”

Examples of a monovalent C₃-C₆₀ carbocyclic group or a monovalent C₁-C₆₀ heterocyclic group may include a C₅-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, and a monovalent non-aromatic condensed heteropolycyclic group.

Examples of a divalent C₃-C₆₀ carbocyclic group or a monovalent C₁-C₆₀ heterocyclic group may include a C₃-C₁₀ cycloalkylene group, a C₁-C₁₀ heterocycloalkylene group, a C₃-C₁₀ cycloalkenylene group, a C₁-C₁₀ heterocycloalkenylene group, a C₆-C₆₀ arylene group, a C₁-C₆₀ heteroarylene group, a divalent non-aromatic condensed polycyclic group, and a divalent non-aromatic condensed heteropolycyclic group.

The term “C₁-C₆₀ alkyl group” as used herein may be a linear or branched monovalent aliphatic hydrocarbon group that has one to sixty carbon atoms, and examples thereof may include a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, a tert-decyl group, and the like. The term “C₁-C₆₀ alkylene group” as used herein may be a divalent group having a same structure as the C₁-C₆₀ alkyl group.

The term “C₂-C₆₀ alkenyl group” as used herein may be a monovalent hydrocarbon group having at least one carbon-carbon double bond in the middle or at a terminus of a C₂-C₆₀ alkyl group, and examples thereof may include an ethenyl group, a propenyl group, a butenyl group, and the like. The term “C₂-C₆₀ alkenylene group” as used herein may be a divalent group having a same structure as the C₂-C₆₀ alkenyl group.

The term “C₂-C₆₀ alkynyl group” as used herein may be a monovalent hydrocarbon group having at least one carbon-carbon triple bond in the middle or at a terminus of a C₂-C₆₀ alkyl group, and examples thereof may include an ethynyl group, a propynyl group, and the like. The term “C₂-C₆₀ alkynylene group” as used herein may be a divalent group having a same structure as the C₂-C₆₀ alkynyl group.

The term “C₁-C₆₀ alkoxy group” as used herein may be a monovalent group represented by-O(A₁₀₁) (wherein A₁₀₁ may be a C₁-C₆₀ alkyl group), and examples thereof may include a methoxy group, an ethoxy group, an isopropyloxy group, and the like.

The term “C₃-C₁₀ cycloalkyl group” as used herein may be a monovalent saturated hydrocarbon cyclic group having 3 to 10 carbon atoms, and examples thereof may include a cyclopropyl group, a cyclobutyl group, a cyclopentyl group, a cyclohexyl group, a cycloheptyl group, a cyclooctyl group, an adamantanyl group, a norbornanyl group (or bicyclo[2.2.1]heptyl group), a bicyclo[1.1.1]pentyl group, a bicyclo[2.1.1]hexyl group, a bicyclo[2.2.2]octyl group, and the like. The term “C₃-C₁₀ cycloalkylene group” as used herein may be a divalent group having a same structure as the C₃-C₁₀ cycloalkyl group.

The term “C₁-C₁₀ heterocycloalkyl group” as used herein may be a monovalent cyclic group having 1 to 10 carbon atoms, further including, in addition to carbon atoms, at least one heteroatom as ring-forming atoms, and examples thereof may include a 1,2,3,4-oxatriazolidinyl group, a tetrahydrofuranyl group, a tetrahydrothiophenyl group, and the like. The term “C₁-C₁₀ heterocycloalkylene group” as used herein may be a divalent group having a same structure as the C₁-C₁₀ heterocycloalkyl group.

The term “C₃-C₁₀ cycloalkenyl group” as used herein may be a monovalent cyclic group that has three to ten carbon atoms and at least one carbon-carbon double bond in the cyclic structure thereof and no aromaticity, and examples thereof may include a cyclopentenyl group, a cyclohexenyl group, a cycloheptenyl group, and the like. The term “C₃-C₁₀ cycloalkenylene group” as used herein may be a divalent group having a same structure as the C₃-C₁₀ cycloalkenyl group.

The term “C₁-C₁₀ heterocycloalkenyl group” as used herein may be a monovalent cyclic group having 1 to 10 carbon atoms, further including, in addition to carbon atoms, at least one heteroatom as ring-forming atoms, and having at least one carbon-carbon double bond in the cyclic structure thereof. Examples of a C₁-C₁₀ heterocycloalkenyl group may include a 4,5-dihydro-1,2,3,4-oxatriazolyl group, a 2,3-dihydrofuranyl group, a 2,3-dihydrothiophenyl group, and the like. The term “C₁-C₁₀ heterocycloalkenylene group” as used herein may be a divalent group having a same structure as the C₁-C₁₀ heterocycloalkenyl group.

The term “C₆-C₆₀ aryl group” as used herein may be a monovalent group having a carbocyclic aromatic system of 6 to 60 carbon atoms. The term “C₆-C₆₀ arylene group” as used herein may be a divalent group having a carbocyclic aromatic system of 6 to 60 carbon atoms. Examples of a C₆-C₆₀ aryl group may include a phenyl group, a pentalenyl group, a naphthyl group, an azulenyl group, an indacenyl group, an acenaphthyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a heptalenyl group, a naphthacenyl group, a picenyl group, a hexacenyl group, a pentacenyl group, a rubicenyl group, a coronenyl group, an ovalenyl group, and the like. When the C₆-C₆₀ aryl group and the C₆-C₆₀ arylene group each include two or more rings, the respective rings may be condensed with each other.

The term “C₁-C₆₀ heteroaryl group” as used herein may be a monovalent group having a heterocyclic aromatic system of 1 to 60 carbon atoms, further including, in addition to carbon atoms, at least one heteroatom as ring-forming atoms. The term “C₁-C₆₀ heteroarylene group” as used herein may be a divalent group having a heterocyclic aromatic system of 1 to 60 carbon atoms, further including, in addition to carbon atoms, at least one heteroatom as ring-forming atoms. Examples of a C₁-C₆₀ heteroaryl group may include a pyridinyl group, a pyrimidinyl group, a pyrazinyl group, a pyridazinyl group, a triazinyl group, a quinolinyl group, a benzoquinolinyl group, an isoquinolinyl group, a benzoisoquinolinyl group, a quinoxalinyl group, a benzoquinoxalinyl group, a quinazolinyl group, a benzoquinazolinyl group, a cinnolinyl group, a phenanthrolinyl group, a phthalazinyl group, a naphthyridinyl group, and the like. When the C₁-C₆₀ heteroaryl group and the C₁-C₆₀ heteroarylene group each include two or more rings, the respective rings may be condensed with each other.

The term “monovalent non-aromatic condensed polycyclic group” as used herein may be a monovalent group (for example, having 8 to 60 carbon atoms) having two or more rings condensed to each other, only carbon atoms as ring-forming atoms, and no aromaticity in its molecular structure as a whole. Examples of a monovalent non-aromatic condensed polycyclic group may include an indenyl group, a fluorenyl group, a spiro-bifluorenyl group, a benzofluorenyl group, an indenophenanthrenyl group, an indenoanthracenyl group, and the like. The term “divalent non-aromatic condensed polycyclic group” as used herein may be a divalent group having a same structure as the monovalent non-aromatic condensed polycyclic group described above.

The term “monovalent non-aromatic condensed heteropolycyclic group” as used herein may be a monovalent group (for example, having 1 to 60 carbon atoms) having two or more rings condensed to each other, further including, in addition to carbon atoms, at least one heteroatom as ring-forming atoms, and having no aromaticity in its molecular structure as a whole. Examples of a monovalent non-aromatic condensed heteropolycyclic group may include a pyrrolyl group, a thiophenyl group, a furanyl group, an indolyl group, a benzoindolyl group, a naphthoindolyl group, an isoindolyl group, a benzoisoindolyl group, a naphthoisoindolyl group, a benzosilolyl group, a benzothiophenyl group, a benzofuranyl group, a carbazolyl group, a dibenzosilolyl group, a dibenzothiophenyl group, a dibenzofuranyl group, an azacarbazolyl group, an azafluorenyl group, an azadibenzosilolyl group, an azadibenzothiophenyl group, an azadibenzofuranyl group, a pyrazolyl group, an imidazolyl group, a triazolyl group, a tetrazolyl group, an oxazolyl group, an isoxazolyl group, a thiazolyl group, an isothiazolyl group, an oxadiazolyl group, a thiadiazolyl group, a benzopyrazolyl group, a benzimidazolyl group, a benzoxazolyl group, a benzothiazolyl group, a benzoxadiazolyl group, a benzothiadiazolyl group, an imidazopyridinyl group, an imidazopyrimidinyl group, an imidazotriazinyl group, an imidazopyrazinyl group, an imidazopyridazinyl group, an indeno carbazolyl group, an indolocarbazolyl group, a benzofurocarbazolyl group, a benzothienocarbazolyl group, a benzosilolocarbazolyl group, a benzoindolocarbazolyl group, a benzocarbazolyl group, a benzonaphthofuranyl group, a benzonaphthothiophenyl group, a benzonaphthosilolyl group, a benzofurodibenzofuranyl group, a benzofurodibenzothiophenyl group, a benzothienodibenzothiophenyl group, and the like. The term “divalent non-aromatic condensed heteropolycyclic group” as used herein may be a divalent group having a same structure as the monovalent non-aromatic condensed heteropolycyclic group described above.

The term “C₆-C₆₀ aryloxy group” as used herein may be a group represented by-O(A₁₀₂) (wherein A₁₀₂ may be a C₆-C₆₀ aryl group), and the term “C₆-C₆₀ arylthio group” as used herein may be a group represented by-S(A₁₀₃) (wherein A₁₀₃ may be a C₆-C₆₀ aryl group).

The term “C₇-C₆₀ arylalkyl group” as used herein may be a group represented by-(A₁₀₄) (A₁₀₅) (wherein A₁₀₄ may be a C₁-C₅₄ alkylene group, and A₁₀₅ may be a C₆-C₅₉ aryl group), and the term “C₂-C₆₀ heteroarylalkyl group” as used herein may be a group represented by-(A₁₀₆) (A₁₀₇) (wherein A₁₀₆ may be a C₁-C₅₉ alkylene group, and A₁₀₇ may be a C₁-C₅₉ heteroaryl group).

In the specification, the group R₁₀ₐ may be:

deuterium, —F, —Cl, —Br, —I, a hydroxyl group, a cyano group, or a nitro group;

a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;

a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, or a C₂-C₆₀ heteroaryl alkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₅-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or —Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂).

In the specification, the groups Q₁ to Q₃, Q₁₁ to Q₁₃, Q₂₁ to Q₂₃, and Q₃₁ to Q₃₃ may each independently be: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₅-C₆₀ carbocyclic group, a C₁-C₆₀ heterocyclic group, a C₇-C₆₀ arylalkyl group, or a C₂-C₆₀ heteroarylalkyl group each unsubstituted or substituted with deuterium, —F, a cyano group, a C₁-C₆₀ alkyl group, a C₁-C₆₀ alkoxy group, a phenyl group, a biphenyl group, or any combination thereof.

The term “heteroatom” as used herein may be any atom other than a carbon atom or a hydrogen atom. Examples of a heteroatom may include O, S, N, P, Si, B, Ge, Se, and any combination thereof.

The term “third-row transition metal” as used herein may be Hf, Ta, W, Re, Os, Ir, Pt, Au, or the like.

In the specification, “Ph” refers to a phenyl group, “Me” refers to a methyl group, “Et” refers to an ethyl group, “tert-Bu” or “But” each refers to a tert-butyl group, and “OMe” refers to a methoxy group.

The term “biphenyl group” as used herein may be a “phenyl group substituted with a phenyl group.” For example, the “biphenyl group” may be a substituted phenyl group having a C₆-C₆₀ aryl group as a substituent.

The term “terphenyl group” as used herein may be a “phenyl group substituted with a biphenyl group”. For example, the “terphenyl group” may be a substituted phenyl group having, as a substituent, a C₆-C₆₀ aryl group substituted with a C₆-C₆₀ aryl group.

The symbols * and *′ as used herein, unless defined otherwise, each refer to a binding site to a neighboring atom in a corresponding formula or moiety.

Hereinafter, a quantum dot composition and a light-emitting device according to embodiments will be described in detail with reference to the Examples below. The wording “B was used instead of A” used in describing Examples refers to that an identical molar equivalent of B was used in place of A.

### EXAMPLES

Table 1 shows the boiling point, vapor pressure, surface tension, and Hansen solubility parameters (HSP) of solvents and cross-linking agents used in Examples and Comparative Examples of the disclosure. In the description below, CHBz represents cyclohexylbenzene, OCBz represents octylbenzene, and HD represents hexadecane.

TABLE 1

| | Boiling | Vapor | Surface | | | | |
|---|---|---|---|---|---|---|---|
| | point | pressure | tension | | | | |
| | (° C.) | (mmHg) | (dyn/cm) | δ(HSP) | δD | δP | δH |
| CHBz | 231 | 0.0786 | 34 | 18.0 | 17.8 | 1.5 | 2.7 |
| OCBz | 264 | 0.0065 | 31 | 17.1 | 16.9 | 1.4 | 2.1 |
| HD | 282 | 0.0016 | 27 | 15.9 | 15.9 | 0.1 | 0.1 |
| CHBz:HD (6:4) | — | — | 31 | 17.3 | 17.2 | 1.1 | 1.9 |
| CHBz:OCBz:HD (6:1:3) | — | — | 31 | 17.9 | 17.7 | 1.5 | 2.6 |
| IP-6Bx | — | — | — | 32.8 | 18.4 | 21.1 | 17.1 |

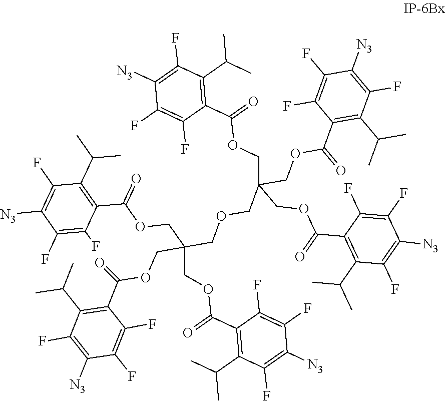 [SMILES: CC(C)c1c(F)c(N=[N+]=[N-])c(F)c(F)c1C(=O)OCC(COCC(COC(=O)c1c(F)c(F)c(N=[N+]=[N-])c(F)c1C(C)C)(COC(=O)c1c(F)c(F)c(N=[N+]=[N-])c(F)c1C(C)C)COC(=O)c1c(F)c(F)c(N=[N+]=[N-])c(F)c1C(C)C)(COC(=O)c1c(F)c(F)c(N=[N+]=[N-])c(F)c1C(C)C)COC(=O)c1c(F)c(F)c(N=[N+]=[N-])c(F)c1C(C)C]

### Preparation of Quantum Dot Composition

### Compositions 1 to 3 and Comparison Compositions 1 to 9

Compositions each including InP quantum dots, a dispersant, a cross-linking agent, and a solvent were prepared. Detailed descriptions of the compositions are shown in Table 2. The InP quantum dots had an average particle diameter of 4 nm, included dodecanethiol (DDT) ligands and emitted green light, and an amount of the quantum dots in the compositions was 1.5 wt %, relative to the solvent. Oleic acid (OA) was used as the dispersant, and an amount of the oleic acid in the compositions was 10%, relative to the weight of the quantum dots. With respect to the cross-linking agent, the compounds shown in Table 2 were used in the indicated amounts. With respect to the solvent, a mixed solvent containing cyclohexylbenzene (CHBz):octylbenzene (OCBz):hexadecane (HD) at a weight ratio of 6:1:3 or a mixed solvent including cyclohexylbenzene (CHBz):hexadecane (HD) at a weight ratio of 6:4 was used.

TABLE 2

| | Quantum | | | |
|---|---|---|---|---|
| | dot | Dispersant | Cross-linking agent | Solvent |
| Composition 1 | InP | Oleic acid | IP-6Bx (1%) | CHBz:OCBz:HD |
| | | (10%) | | (6:1:3) |
| Composition 2 | InP | Oleic acid | IP-6Bx (3%) | CHBz:OCBz:HD |
| | | (10%) | | (6:1:3) |
| Composition 3 | InP | Oleic acid | IP-6Bx (5%) | CHBz:OCBz:HD |
| | | (10%) | | (6:1:3) |
| Comparison | InP | Oleic acid | IP-6Bx (1%) | CHBz:HD (6:4) |
| Composition 1 | | (10%) | | |
| Comparison | InP | Oleic acid | DAB (1%) | CHBz:HD (6:4) |
| Composition 2 | | (10%) | | |
| Comparison | InP | Oleic acid | DAB (5%) | CHBz:HD (6:4) |
| Composition 3 | | (10%) | | |
| Comparison | InP | Oleic acid | DAB (8%) | CHBz:HD (6:4) |
| Composition 4 | | (10%) | | |
| Comparison | InP | Oleic acid | DAB (15%) | CHBz:HD (6:4) |
| Composition 5 | | (10%) | | |
| Comparison | InP | Oleic acid | Bisperfluorobenzoazide | CHBz:HD (6:4) |
| Composition 6 | | (10%) | (5%) | |
| Comparison | InP | Oleic acid | 1,4-diazidobenzene (5%) | CHBz:HD (6:4) |
| Composition 7 | | (10%) | | |
| Comparison | InP | Oleic acid | 4,4′-diazidodiphenyl- | CHBz:HD (6:4) |
| Composition 8 | | (10%) | ethane (5%) | |
| Comparison | InP | Oleic acid | 2,6-bis(4- | CHBz:HD (6:4) |
| Composition 9 | | (10%) | azidobenzylidene)cyclo- | |
| | | | hexanone (5%) | |

### Measurement of Photoluminescence Quantum Yield (PLOY)

The PLQY of Compositions 1 to 3 and Comparison Compositions 1 and 2 was measured by using by using QE-2100 equipment manufactured by Otsuka Company, and results thereof are shown in Table 3.

TABLE 3

| Composition | PLQY (%) |
|---|---|
| Composition 1 | 98 |
| Composition 2 | 96 |
| Composition 3 | 97 |
| Comparison | 97 |
| Composition 1 | |
| Comparison | 99 |
| Composition 2 | |

Referring to Table 2, it was confirmed that the PLQY of Compositions 1 to 3 and Comparison Composition 1 using IP-6Bx as the cross-linking agent of the quantum dot composition and the PLQY of Comparison Composition 2 using DAB as the cross-linking agent of the quantum dot composition were all maintained high values of 96% or higher.

### Preparation of Quantum Dot Layer

### Examples 1 to 3 and Comparative Examples 1 and 2

An OLED ITO glass substrate (manufactured by Samsung-Corning Company) (50 mm×50 mm×0.5 mm, 15 Ω/cm²) was sequentially ultrasonicated with distilled water and isopropanol, and subjected to UV ozone cleaning for 30 minutes. Following the cleaning, ZnMgO, which was used for forming an electron transport layer, was spin-coated on the ITO glass substrate, and baked at 230° C. for 10 minutes to form a ZnMgO layer having a thickness of 35 nm. Compositions 1 to 3 and Comparison Compositions 1 and 2 of Table 2 were each spin-coated on the ZnMgO layer, and baked at 140° C. for 10 minutes to form a quantum dot layer having a thickness of 20 nm of each of Examples 1 to 3 and Comparative Examples 1 and 2.

### Measurement of Agglomeration Rate

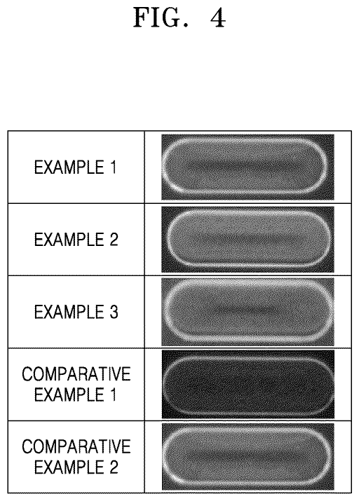

The agglomeration rates for the quantum dot layers of Examples 1 to 3 and Comparative Examples 1 and 2 were measured, and results thereof are shown in Table 4. The agglomeration rate refers to the ratio of the area of the aggregated portion to the total area of the quantum dot layer. To calculate the agglomeration rate, the upper surface of the quantum dot layer formed on the ZnMgO layer was photographed with an optical microscope, and the area of the visually confirmed agglomerated portion was measured. FIG. 4 shows optical micrographs of the quantum dot layers of Examples 1 to 3 and Comparative Examples 1 and 2 used to calculate the agglomeration rate.

TABLE 4

| Quantum | | Agglomeration |
|---|---|---|
| dot layer | Composition | rate |
| Example 1 | Composition 1 | 5 |
| Example 2 | Composition 2 | 5 |
| Example 3 | Composition 3 | 5 |
| Comparative | Comparison | 17 |
| Example 1 | Composition 1 | |
| Comparative | Comparison | 4 |
| Example 2 | Composition 2 | |

Referring to Table 4, the agglomeration rates of the quantum dot layers of Examples 1 to 3 and Comparative Example 2 were good at 4 to 5, whereas the agglomeration rate of the quantum dot layer of Comparative Example 1 was high at 17. Referring to FIG. 4, a round-shaped agglomerated portion was clearly visible in the quantum dot layer of Comparative Example 1. The reason for a high agglomeration rate of the quantum dot layer of Comparative Example 1 is considered to be due to low solubility of IP-6Bx in the mixed solvent of CHBz:HD in Comparison Composition 1. It was considered that the quantum dot layers of Examples 1 to 3 had low agglomeration rates due to increased solubility of IP-6Bx in the mixed solvent of CHBz:OCBz:HD in Compositions 1 to 3. It was considered that the quantum dot layer of Comparative Example 2 had a low agglomeration rate due to high solubility of DAB in the mixed solvent of CHBz:HD in Comparison Composition 2.

### Manufacture of Light-Emitting Device

### Examples 4 and 5 and Comparative Examples 3 to 6

An OLED ITO glass substrate (manufactured by Samsung-Corning Company) (50 mm×50 mm×0.5 mm, 15 Ω/cm²) was sequentially ultrasonicated with distilled water and isopropanol, and subjected to UV ozone cleaning for 30 minutes. Following the cleaning, ZnMgO was spin-coated on the ITO glass substrate, and baked at 230° C. for 10 minutes to form an electron transport layer having a thickness of 35 nm. As described in Table 5, the Compositions and Comparison Compositions were each spin-coated on the electron transport layer, and baked at 140° C. for 10 minutes to form a green emission layer having a thickness of 20 nm. NPB(NPD) was spin-coated on the green emission layer, and baked at 200° C. for 10 minutes to form a hole transport layer having a thickness of 30 nm. As shown in Table 5, the hole transport layer was formed without a retention time between the spin-coating and the baking or with a retention time therebetween. PEDOT:PSS was spin-coated on the hole transport layer, and baked at 200° C. for 30 minutes to form a hole injection layer having a thickness of 20 nm. AgMg was deposited on the hole injection layer to form an anode having a thickness of 20 nm, thereby completing the manufacture of a light-emitting device.

TABLE 5

| Light- | | | Retention time | | Driving | Current |
|---|---|---|---|---|---|---|
| emitting | | | before baking of hole | | voltage | efficiency |
| device | Emission layer | Cross-linking agent | transporting layer | | (V) | (cd/A) |
| Example 4 | Composition 1 | IP-6Bx (1%) | None | | 5.8 | 52.9 |
| Example 5 | | | 15 | minutes | 5.5 | 34.5 |
| Comparative | Comparison | DAB (8%) | None | | 5.8 | 47.6 |
| Example 3 | Composition 4 | | | | | |
| Comparative | | | 15 | minutes | 5.8 | 25.4 |
| Example 4 | | | | | | |
| Comparative | Comparison | DAB (5%) | 15 | minutes | 5.1 | 25.7 |
| Example 5 | Composition 3 | | | | | |
| Comparative | Comparison | DAB (15%) | 15 | minutes | 5.8 | 25.9 |
| Example 6 | Composition 5 | | | | | |
| Comparative | Comparison | Bisperfluorobenzoazide | None | | 5.8 | 51.9 |
| Example 7 | Composition 6 | (5%) | | | | |
| Comparative | | | 15 | minutes | 5.5 | 25.9 |
| Example 8 | | | | | | |
| Comparative | Comparison | 1,4-diazidobenzene (5%) | None | | 5.9 | 48.5 |
| Example 9 | Composition 7 | | | | | |
| Comparative | | | 15 | minutes | 5.7 | 18.9 |
| Example 10 | | | | | | |
| Comparative | Comparison | 4,4′diazidodiphenyl- | None | | 5.8 | 49.1 |
| Example 11 | Composition 8 | ethane (5%) | | | | |
| Comparative | | | 15 | minutes | 5.6 | 21.1 |
| Example 12 | | | | | | |
| Comparative | Comparison | 2,6-bis(4- | None | | 5.9 | 46.7 |
| Example 13 | Composition 9 | azidobenzylidene)cyclo- | | | | |
| Comparative | | hexanone (5%) | 15 | minutes | 5.8 | 16.5 |
| Example 14 | | | | | | |

### Evaluation of Device Characteristics

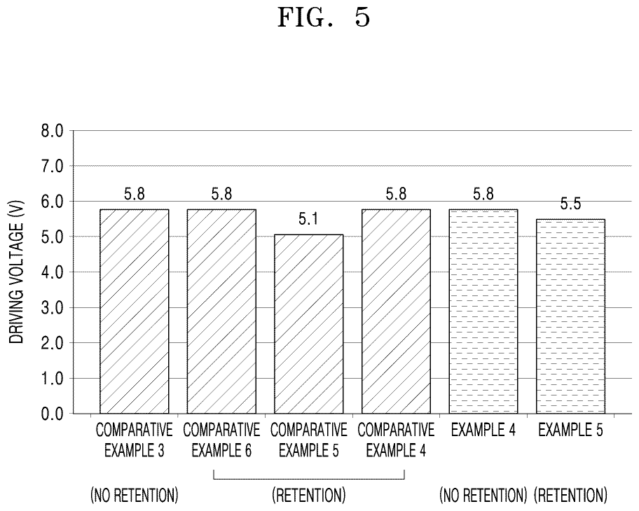

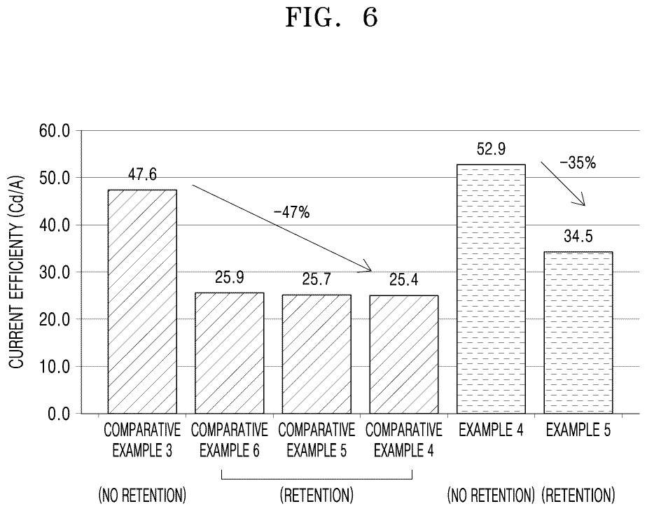

The driving voltage and current efficiency of the light-emitting devices of Examples 4 and 5 and Comparative Examples 3 to 6 were measured, and results thereof are shown in Table 5 and FIGS. 5 and 6.

Referring to Table 5 and FIG. 5, the driving voltage of each of the light-emitting devices of Examples 4 and 5 and Comparative Examples 3 to 6 was between 5.1 V and 5.8 V, and did not significantly change depending on the retention time after spin-coating and before baking when forming the hole transport layer.

Referring to Table 5 and FIG. 6, there is a significant difference in the current efficiency of the light-emitting device depending on the retention time after spin-coating and before baking when forming the hole transport layer.

In the case of the light-emitting device of Example 4 in which baking was performed immediately after spin-coating when forming the hole transport layer, the current efficiency was 52.9 Cd/A, whereas in the case of the light-emitting device of Example 5 in which baking was performed 15 minutes after spin-coating, the current efficiency was 34.5 Cd/A. As shown in Table 5 and FIG. 6, the current efficiency of the light-emitting device of Example 5 was reduced by about 35%, compared to the current efficiency of the light-emitting device of Example 4. In the case of the light-emitting device of Comparative Example 3 in which baking was performed immediately after spin-coating when forming the hole transport layer, the current efficiency was 47.6 Cd/A, whereas in the case of the light-emitting device of Comparative Example 4 in which baking was performed 15 minutes after spin-coating, the current efficiency was 25.4 Cd/A. As shown in Table 5 and FIG. 6, the current efficiency of the light-emitting device of Comparative Example 3 was reduced by about 47% compared to the current efficiency of the light-emitting device of Comparative Example 4.

When baking is performed immediately after spin-coating during formation of the hole transport layer, the exposure time of the emission layer including quantum dots to the solution used for forming the hole transport layer is short or very little. However, when baking is performed after a period of retention after spin-coating during formation of the hole transport layer, the emission layer including quantum dots may be dissolved in the solution used for forming the hole transport layer so that the current efficiency of the light-emitting device may be accordingly reduced.

It was confirmed that the light-emitting device of Example 4 had higher current efficiency than the light-emitting device of Comparative Example 3, and that the light-emitting device of Example 5 had a smaller reduction in the current efficiency than the light-emitting device of Comparative Example 4. This is because the emission layers of the light-emitting devices of Examples 4 and 5 achieved a greater degree of curing than those of the light-emitting devices of Comparative Examples 3 and 4, and thus these emission layers were better able to withstand the solution used for forming the hole transport layer.

In the case of the light-emitting devices of Comparative Examples 4 to 6 in which the concentration of the cross-linking agent, DAB, was changed and baking was performed after a certain period of time after spin-coating when forming the hole transport layer, the current efficiency was similar, but appeared lower than the light-emitting device of Example 5 in which IP-6Bx was used as the cross-linking agent and baking was performed after a certain period of time after spin-coating when forming the hole transport layer.

Even in the case of the light-emitting devices of Comparative Examples 7 to 14, when baking was performed after a certain period of time of spin-coating during formation of the hole transport layer, the current efficiency appeared to drop significantly rapidly compared to the light-emitting devices of Examples 4 and 5.

According to embodiments, a quantum dot composition may have an improved curing degree so that a light-emitting device including an emission layer which is formed by using the quantum dot composition may have improved efficiency.

Embodiments have been disclosed herein, and although terms are employed, they are used and are to be interpreted in a generic and descriptive sense only and not for the purposes of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. A quantum dot composition comprising:
quantum dots;
a cross-linking agent having four or more moieties each independently represented by Formula A; and
a mixed solvent including a first solvent, a second solvent, and a third solvent, wherein
the second solvent has a higher boiling point than the first solvent,
the second solvent has a lower surface tension than the first solvent, and
the third solvent is a compound represented by Formula 3: 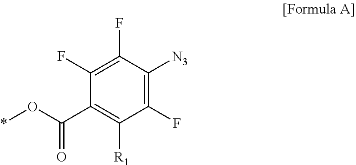
Ar₂—R₂ [Formula 3]
wherein in Formulae A and 3,
R₁ is hydrogen, deuterium, a halogen, or a C₁-C₁₀ alkyl group,
* indicates a binding site to a neighboring atom,
Ar₂ is a substituted or unsubstituted C₆-C₃₀ aryl group, and
R₂ is a linear or branched C₁-C₃₀ alkyl group.

2. The quantum dot composition of claim 1, wherein
the cross-linking agent is a compound represented by Formula 1 or Formula 2: 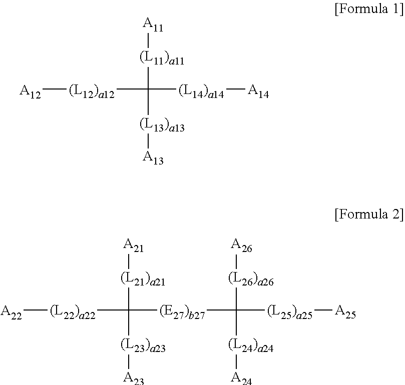
wherein in Formulae 1 and 2,
A₁₁ to A₁₄ are each independently a group represented by Formula A,
A₂₁ to A₂₆ are each independently hydrogen or a group represented by Formula A,
at least one of A₂₁ to A₂₃ and at least one of A₂₄ to A₂₆ are each independently a group represented by Formula A,
L₁₁ to L₁₄ and L₂₁ to L₂₆ are each independently a direct bond or a C₁-C₃ alkylene group,
E₂₇ is a-CH₂—O—CH₂— group, a —CH(R₂₇)— group, or a —C(R₂₇)₂— group,
R₂₇ is a-(L₂₇)ₐ₂₇-A₂₇ group,
L₂₇ is same as described in connection with L₂₁,
A₂₇ is same as described in connection with A₂₁,
a11 to a14 and a21 to a27 are each independently 0 or 1,
b27 is an integer from 1 to 6,
when A₂₁ is hydrogen, a21 is 0,
when A₂₂ is hydrogen, a22 is 0,
when A₂₃ is hydrogen, a23 is 0,
when A₂₄ is hydrogen, a24 is 0,
when A₂₅ is hydrogen, a25 is 0,
when A₂₆ is hydrogen, a26 is 0, and
when A₂₇ is hydrogen, a27 is 0.

3. The quantum dot composition of claim 2, wherein
the cross-linking agent is represented by Formula 1, and
in Formula 1, L₁₁ to L₁₄ are each a-CH₂— group.

4. The quantum dot composition of claim 2, wherein
the cross-linking agent is represented by Formula 2, and
in Formula 2,
b27 is 1, and
E₂₇ is a-CH₂—O—CH₂— group.

5. The quantum dot composition of claim 2, wherein
the cross-linking agent is represented by Formula 2, and
in Formula 2,
b27 is 2, and
each E₂₇ is independently a-CH(R₂₇)— group.

6. The quantum dot composition of claim 2, wherein
the cross-linking agent is represented by Formula 2, and
in Formula 2,
b27 is 3, and
each E₂₇ is independently a-CH₂—O—CH₂— group or a —C(R₂₇)₂— group.

7. The quantum dot composition of claim 1, wherein the cross-linking agent comprises one of compounds below or a combination of the compounds below:

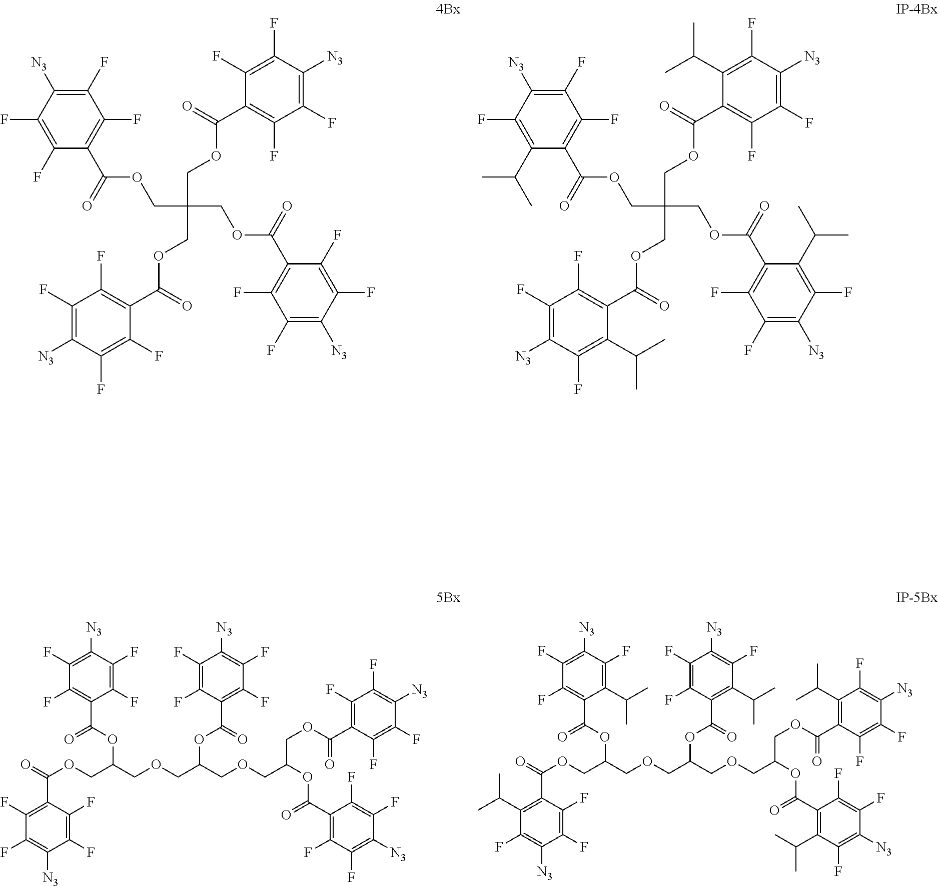

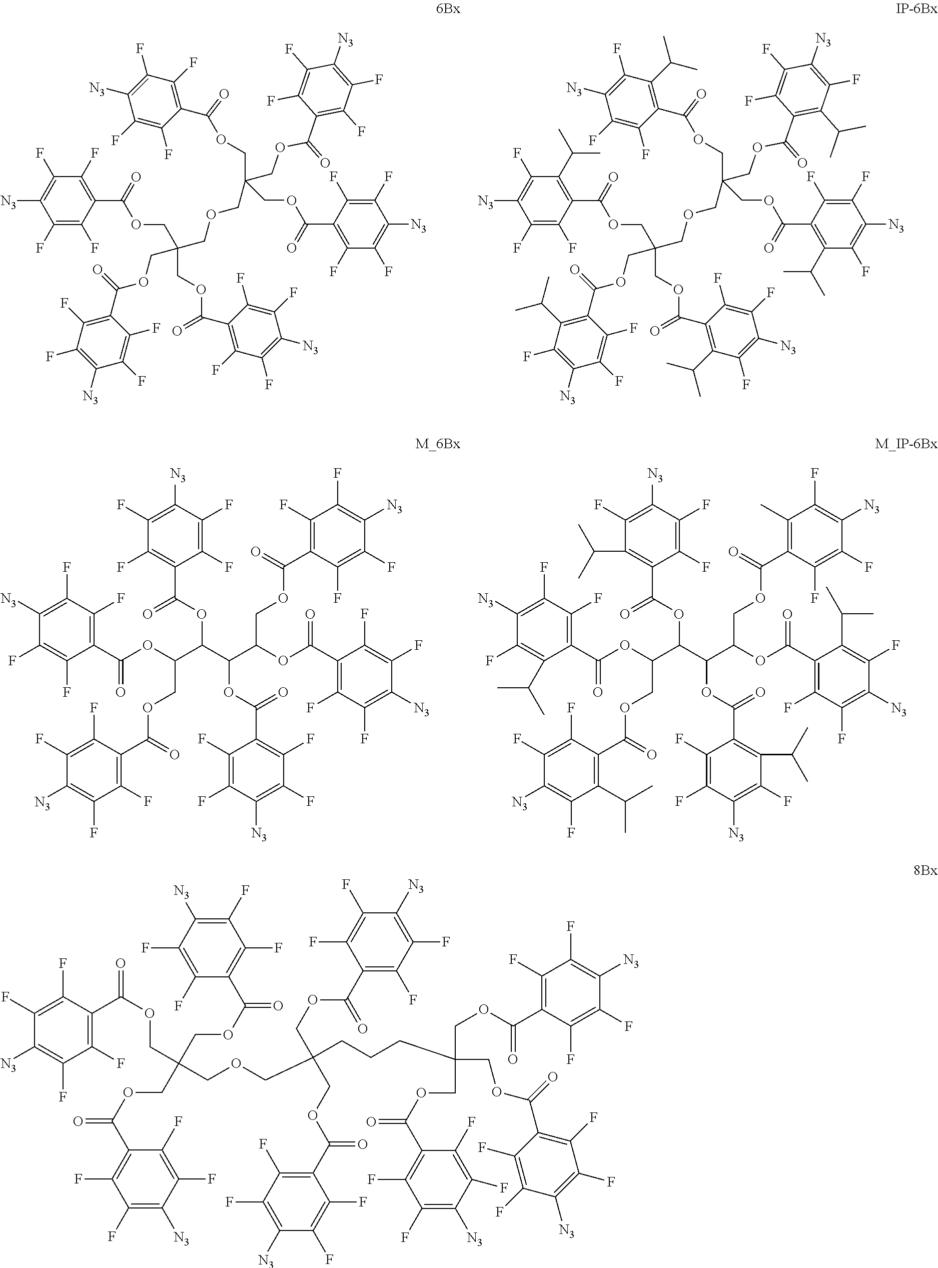

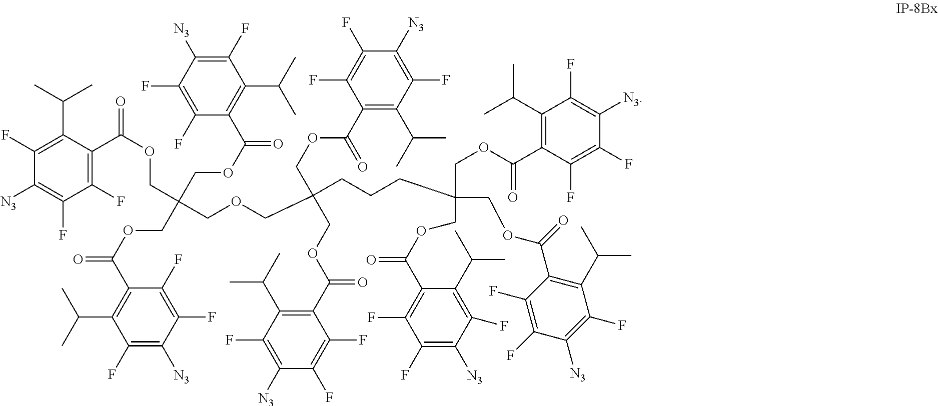 [SMILES: CC(C)c1c(F)c(N=[N+]=[N-])c(F)c(F)c1C(=O)OCC(CCCC(COC(=O)c1c(F)c(F)c(N=[N+]=[N-])c(F)c1C(C)C)(COC(=O)c1c(F)c(F)c(N=[N+]=[N-])c(F)c1C(C)C)COC(=O)c1c(F)c(F)c(N=[N+]=[N-])c(F)c1C(C)C)(COCC(COC(=O)c1c(F)c(F)c(N=[N+]=[N-])c(F)c1C(C)C)(COC(=O)c1c(F)c(F)c(N=[N+]=[N-])c(F)c1C(C)C)COC(=O)c1c(F)c(F)c(N=[N+]=[N-])c(F)c1C(C)C)COC(=O)c1c(F)c(F)c(N=[N+]=[N-])c(F)c1C(C)C]

8. The quantum dot composition of claim 1, wherein in Formula 3,
Ar₂ is a phenyl group, and
R₂ is a methyl group, an ethyl group, a propyl group, a butyl group, a pentyl group, a hexyl group, a heptyl group, an octyl group, a nonyl group, a decyl group, an undecyl group, or a dodecyl group.

9. The quantum dot composition of claim 1, wherein
the first solvent is cyclohexylbenzene,
the second solvent is hexadecane, and
the third solvent is octylbenzene.

10. The quantum dot composition of claim 1, wherein a difference in dispersion (δD) among Hansen solubility parameters (HSP) between the cross-linking agent and the mixed solvent is equal to or less than about 1.1 MPa^{1/2}.

11. The quantum dot composition of claim 1, wherein the mixed solvent has a boiling point equal to or greater than about 200° C.

12. The quantum dot composition of claim 1, wherein the quantum dots emit green light.

13. The quantum dot composition of claim 1, wherein the quantum dots comprise a Group II-VI semiconductor compound, a Group III-V semiconductor compound, a Group III-VI semiconductor compound, a Group I-III-VI semiconductor compound, a Group IV-VI semiconductor compound, a Group IV element or compound, or a combination thereof.

14. The quantum dot composition of claim 1, wherein
the quantum dots each further comprise a ligand on a surface of the quantum dot, and
crosslinks are formed between the ligands by the cross-linking agent.

15. The quantum dot composition of claim 14, wherein the ligand comprises at least one of dodecanethiol (DDT), zinc oleate (ZnOA), zinc(II) 2-ethylhexanoate (Zn(EHA)), and zinc laurate (Zn(LRA)).

16. A light-emitting device comprising:
a first electrode on a substrate;
a second electrode facing the first electrode; and
an organic layer between the first electrode and the second electrode and comprising an emission layer, wherein
the emission layer is formed from the quantum dot composition of claim 1.

17. The light-emitting device of claim 16, wherein
the first electrode is a cathode,
the second electrode is an anode, and
the light-emitting device comprises:
an electron transport region between the first electrode and the emission layer; and
a hole transport region between the second electrode and the emission layer.

18. An electronic apparatus comprising the light-emitting device of claim 16.

19. The electronic apparatus of claim 18, further comprising:
a thin-film transistor, wherein
the thin-film transistor comprises a source electrode and a drain electrode, and
the first electrode of the light-emitting device is electrically connected to at least one of the source electrode and the drain electrode.

20. The electronic apparatus of claim 19, further comprising:
a color filter, a color conversion layer, a touch screen layer, a polarizing layer, or a combination thereof.
